(19) United States
(12) Patent Application Publication
(10) Pub. No.: US 2026/0147957 A1
(43) Pub. Date: May 28, 2026

(54) SYSTEMS AND METHODS FOR IMPROVED IMPLICIT COMPUTER AIDED DESIGN (CAD)

(71) Applicant: nTopology Inc., New York, NY (US)

(72) Inventors: Bradley ROTHENBERG, New York, NY (US); George ALLEN, Nakijin (JP); Ranjeeth MAHANKALI, New York, NY (US)

(21) Appl. No.: 19/280,852

(22) Filed: Jul. 25, 2025

Related U.S. Application Data
(60) Provisional application No. 63/724,122, filed on Nov. 22, 2024.

(51) Int. Cl. G06F 30/20; G06F 30/12

(52) U.S. Cl. CPC G06F 30/20; G06F 30/12

(57) ABSTRACT

Systems and methods applicable, for instance, to implicit CAD. Tracking one or more computational characteristics during a multi-step computation of function values corresponding to points on a 3-dimensional CAD body may be used to implement various computer-aided design functions such as identifying portions of originally provided geometries, eliminating unnecessary computational steps, efficiently troubleshooting a design workflow, and identifying surface boundaries and intersections, among others.

### CROSS-REFERENCE TO RELATED APPLICATIONS

This application claims priority to U.S. Provisional Patent Application No. 63/697,971, entitled “COMPUTATIONAL DESIGN AND INTEGRATION INTO THE DIGITAL THREAD,” which was filed on Sep. 23, 2024, the disclosure of which is herein incorporated by reference in its entirety and for all purposes.

### FIELD

The present disclosure relates generally to computer aided design (CAD), and more specifically, but not exclusively, to improved implicit CAD.

### BACKGROUND

Considering the history of CAD, early CAD systems include constructive solid geometry (CSG) systems. Later, these CSG systems were, for the most part, replaced by systems utilizing boundary representations (B-Reps). From one point of view, links between these two types of modeling can be perceived. However, implicit modeling seems to stand on its own. Composing mathematical functions that represent scalar fields, and defining shapes as zero level isosurfaces of those scalar fields seems alien to traditional CAD (e.g., CSG-based CAD or b-rep-based CAD).

On one hand, implicit CAD has capabilities that traditional CAD lacks. For example, implicit CAD provides increased reliability compared to traditional CAD approaches. As just some illustrations, when implicit CAD is used operations tend not to break, and blends and unions tend to always work. As another example, implicit CAD provides increased efficiency compared to traditional CAD approaches. As one illustration of such increased efficiency, when implicit CAD approaches are employed, a lattice with a thousand unit cells can be represented just as efficiently as a lattice with a million unit cells. As a further illustration of such increased efficiency, when implicit CAD approaches are employed complex geometry such as triply periodic minimal surfaces (TPMs) can be represented with simple equations, and without using up memory for millions of triangles.

But, on the other hand, traditional CAD can provide various capabilities that implicit modeling typically does not. As just some illustrations, traditional CAD is typically capable of performing surface intersections, and is typically further capable of creating connected faces (e.g., faces that are connected to edges and/or to other faces). Knowing the features of a surface can be useful. For example, boundary conditions can be defined on CAD faces. As another example, computer aided manufacturing (CAM) software can use edges as guides for generating tool paths.

Such functionality that is offered by traditional CAD but not typically offered by implicit CAD can, as just some examples, aid in capturing modeling intent, and make it easier to produce meshes with sharp edges. Further, many workflows tend to rely on such functionality that is offered by traditional CAD but not typically offered by implicit CAD.

Conventional implicit modeling does not offer the functionalities just discussed. According to conventional approaches, implicit bodies are black box mathematical functions with no knowledge of features or faces. Certain existing approaches attempt to connect implicit CAD with non-implicit CAD via interoperability functionality. But, at least according to conventional approaches, interoperability typically yields unsatisfactory results. Unsatisfactory interoperability can result in various problems including the island problem.

In view of the foregoing, a need exists for improved systems and methods for implicit CAD, in an effort to overcome the aforementioned obstacles and deficiencies of conventional approaches. The functionality discussed herein addresses obstacles and deficiencies including the aforementioned by, for instance, utilizing trackers that embed additional logic that can be run during evaluation of a graph (or tree) corresponding to an implicit body, and/or through the use of improved implicit CAD kernels. Various aspects will now be discussed in greater detail.

### BRIEF DESCRIPTION OF THE DRAWINGS

The novel features of the disclosed systems and methods are set forth with particularity in the appended claims. A better understanding of the features and advantages of the present systems and methods will be obtained by reference to the following detailed description that sets forth illustrative embodiments, in which the principles of the invention are used, and the accompanying drawings (also “Fig.,” “FIG.,” “Figure,” “Figures,” “Figs.,” and “FIGs.” herein) of which:

FIG. 1 shows an example of placing color using hashes from trackers, according to various embodiments.

FIG. 2 shows a further example of placing color using hashes from trackers, according to various embodiments.

FIG. 3 shows an additional example of placing color using hashes from trackers, according to various embodiments.

FIG. 4 shows another example of placing color using hashes from trackers, according to various embodiments.

FIG. 5 depicts relationships between implicit CAD and traditional CAD, according to various embodiments.

FIG. 6 shows an example of merging, according to various embodiments.

FIG. 7 shows an example comparison of implicit modeling approaches, according to various embodiments.

FIG. 8 shows a further example comparison of implicit modeling approaches, according to various embodiments.

FIG. 9A shows an example of tracing results in an implicit body back to original implicits and corresponding parameters, according to various embodiments.

FIG. 9B shows further detail regarding the implicit body of FIG. 9A.

FIG. 10A shows a further example of tracing results in an implicit body back to original implicits and corresponding parameters, according to various embodiments.

FIG. 10B shows further detail regarding the implicit body of FIG. 10A.

FIG. 11 shows an example of using forward mode automatic differentiation (AD) on the abstract semantic graph (ASG) level, according to various embodiments.

FIG. 12 shows an example of transforming an abstract syntax tree (AST) from a first state to a second state, according to various embodiments.

FIG. 13 shows an example computer, according to various embodiments.

FIG. 14 is a flowchart depicting a method of computer-aided design, according to aspects of the present teachings.

FIG. 15 is a flowchart depicting another method of computer-aided design, according to aspects of the present teachings.

FIG. 16 is a flowchart depicting yet another method of computer-aided design, according to aspects of the present teachings.

FIG. 17A depicts a 3-dimensional CAD body that includes a sphere partially embedded in a cube.

FIG. 17B depicts the 3-dimensional CAD body of FIG. 17A, with the sphere subtracted from the CAD body, leaving a cube with an indentation in the shape of part of a sphere.

It should be noted that the figures are not drawn to scale and that elements of similar structures or functions are generally represented by like reference numerals for illustrative purposes throughout the figures. It also should be noted that the figures are only intended to facilitate the description of the preferred embodiments. The figures do not illustrate every aspect of the described embodiments and do not limit the scope of the present disclosure.

### DETAILED DESCRIPTION

Implicit bodies, in an aspect, correspond to zero isosurfaces of scalar fields that are established by composing mathematical operations (e.g., signed distance functions (SDFs)). These mathematical operations can, as just some examples be represented as graphs (e.g., as abstract semantic graphs (ASGs)) and/or as trees (e.g., as abstract syntax trees (ASTs)). Such graphs and trees can be referred to as syntax representations. To facilitate discussion, the mathematical operations will, in general, be described as being represented as graphs, with the understanding that other possibilities exist.

By evaluating such a graph representing such mathematical operations, the field value at any point can be computed. As one example, the graph can be evaluated directly. As another example, the graph can first be transpiled into another format. By first transpiling the graph into another format, benefits including making it easier and/or faster to evaluate the graph can accrue.

As one example of transpiling the graph into another format, the graph can be transpiled into bytecode (e.g., for evaluation by a CPU). Where the graph is transpiled into bytecode, corresponding computations can be lowered from vectors and matrices down to floating point calculations. This lowering can make it easier to perform various optimizations. This lowering can also facilitate actions such as pruning.

As another example of transpiling the graph into other formats, the graph can be transpiled into OpenGL shading language (GLSL) (e.g., for evaluation by a GPU). Transpiling the graph into GLSL can yield benefits including massive parallelism. As yet another example of transpiling the graph into other formats, the graph can be transpiled to machine code. Transpiling the graph into machine code can yield benefits including faster CPU execution, and/or more efficient memory access and/or usage.

According to various embodiments, trackers can be used to embed additional logic to be run during the evaluation of the graph. A wide variety of trackers serving a wide variety of purposes can be constructed. A process that runs the trackers (e.g., an implicit kernel that interprets the graph) can be agnostic as to what these trackers are and how they are used (e.g., how they are used in workflows). It is further noted that trackers can be tailored for specific workflows.

As one example, trackers can be used to make decisions that are called for by various workflows. As another example, trackers can be used to observe, record, and/or make decisions based on the calculations that are performed as part of the evaluation of the graph. As an additional example, trackers can be used in connection with slicing code. Here, a tracker can be employed to identify calculations and/or instructions that do not contribute to the final field value in a region, and/or to prune such calculations and/or instructions. In this way, benefits including improved performance can be realized.

As yet another example, trackers can be used in connection with a meshing block. Here, a tracker can be employed to identify regions where the field value is coming directly from an existing mesh and/or CAD body. The tracker can use this knowledge, for instance, to reuse the triangles from the source mesh, and/or to reuse the tessellation of the source CAD part.

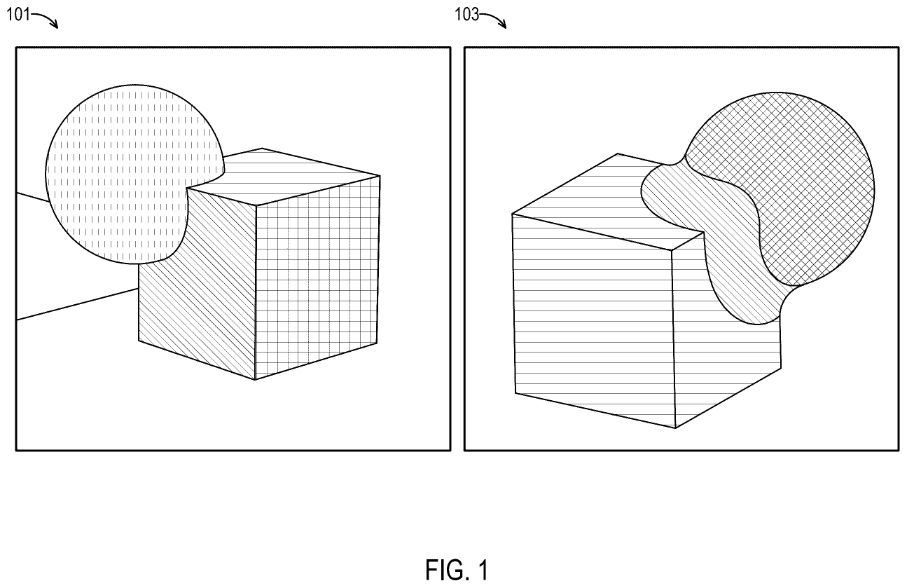

As a further example, a tracker can be constructed that computes a fingerprint and/or hash (e.g., a unique fingerprint and/or hash) for the set of calculations that goes into computing the field value at a point. As just an illustration, this fingerprint and/or hash can be used to assign a unique color to such a point. Turning to FIG. 1, shown are two such examples, in particular two sphere cubes (101, 103) colored with fingerprints and/or hashes from two different trackers. According to these examples, the tracker of the leftmost sphere cube 101 is more discerning than the tracker of the rightmost sphere cube 103. As such, it assigns a different color to each face of the leftmost cube. In contrast, the tracker of the rightmost sphere cube assigns the same color to all cube faces. To facilitate discussion, the noted fingerprints and hashes will, in general, be referred to as hashes, with the understanding that other possibilities exist.

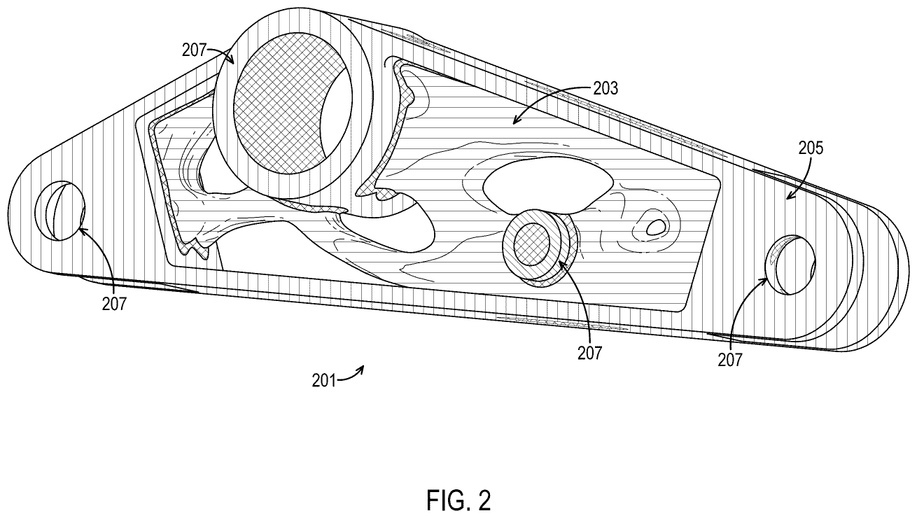

Turning to FIG. 2, shown is an example of a part 201 colored using a tracker of the sort just discussed. The coloring yielded by the tracker allows a viewer to distinguish between: a) the regions that come from topology optimization (i.e., the central bracket portion 203 where material has been removed by the optimization, based on provided loading conditions); b) the regions that come from CAD (i.e., the outer bracket portions 205 and the four holes 207); and c) the regions that blend between the two.

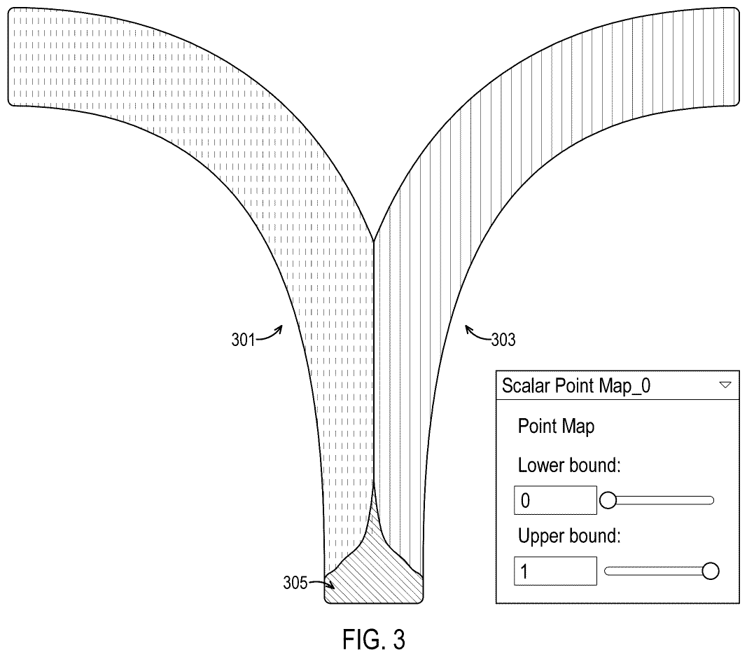

Turning to FIG. 3, shown is an example of two pipes (301, 303) merging into one, colored using a further tracker of the sort just discussed. The coloring yielded by this tracker allows a viewer to distinguish between: a) a first of the two pipes 301; b) a second of the two pipes 303; and c) the region 305 that blends between the first pipe 301 and the second pipe 303.

The discussed colors yielded by trackers in one aspect each come from a hash (e.g., a unique hash). But, in another aspect, the discussed colors each point to a subgraph (or subtree), of the corresponding implicit body, that contributes to the corresponding field in the corresponding region. From one point of view, a given colored region can be thought of as one or more parts of an implicit subgraph (or subtree) that survive in the final implicit.

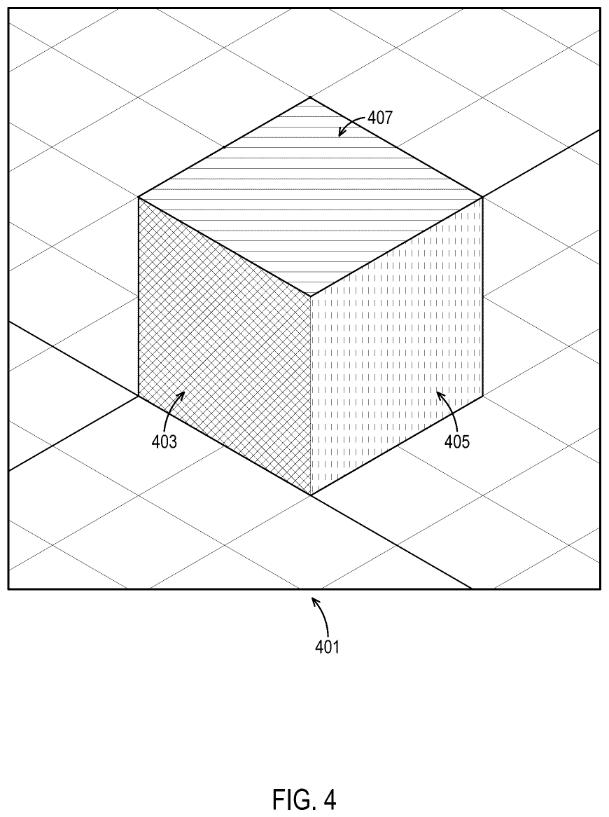

Turning to FIG. 4, shown is an example of a part 401 colored using a tracker of the sort discussed. Here the part is a box modeled by performing a Boolean intersection of six halfspaces (halfspaces 403, 405, and 407 shown; other halfspaces not shown). As such, the graph (or tree) for the box can contain several max nodes to intersect the halfspaces.

According to the example of FIG. 4, a given tracking hash in one aspect is the identity of the subgraph (or subtree) that a corresponding field value came from. Also according to the example of FIG. 4 a given tracking hash, in another aspect is the identity of the subgraph (or subtree) that provides a corresponding one of the halfspaces. Moreover, a face of an implicit body can be established (e.g., by an implicit kernel) as those points on the surface of the implicit body that track to a particular subgraph (or subtree) of the implicit body. With reference to the example of FIG. 4, it is noted that the halfspaces can be unbounded, but a given face can be bounded because only a portion of it survives in the final box after all the Boolean intersections.

According to various embodiments, stored along with a given portion (e.g., subgraph or subtree) of a graph or tree can be the tracking hash that has been computed for that portion. Further, stored along with an implicit face (e.g., stored along with a given voxel or stored along with each voxel of an implicit face) can be the tracking hash for the graph (or tree) portion that corresponds to that implicit face. As such, ascertaining the graph (or tree) portion that is associated with (i.e., tracks to) a given implicit face can involve determining the stored tracking hash for that implicit face, and then finding in the graph (or tree) a portion having a matching stored hash. As just some examples, a Secure Hash Algorithm (SHA) algorithm (e.g., sha256) and/or a message digest (MD) algorithm (e.g., MD5) can be used to compute a tracking hash for a given graph (or tree) portion.

The face of an implicit can be used in a variety of ways. As an example, one or more boundary conditions can be defined for such an implicit face (e.g., in order to support one or more simulations). Here the relevant boundary condition data can be associated with the subgraph (or subtree) that corresponds to the implicit face. For simulations that use meshes, this boundary condition data can be transferred to those mesh nodes that track to the same subgraph (or subtree) as the implicit face (i.e., to those mesh nodes that lie on the implicit face). For simulations that do not use meshes (e.g., for simulations that use a background grid), the boundary condition data can be transferred to those voxels that track to the same subgraph (or subtree) as the implicit face (e.g., to those voxels that the implicit face passes through).

As another example, an implicit face can be extruded, such as for purposes of modeling a separate part and/or solid. More generally, an implicit face can (e.g., in connection with selection by a user) be used in place of a conventional CAD face for circumstances where conventional CAD faces can be employed. As such, the implicit faces discussed herein can not only be viewable as colored regions that visually resemble conventional CAD faces, but can also be used in providing (e.g., by way of a CAD UI) the CAD functionality that is furnished by those conventional CAD faces (e.g., simulation functionality). Further as such, implicit faces according to the functionality discussed herein can allow implicit bodies to not only have geometry, but also to have topology.

In one aspect, implicit modeling differs from CSG modeling insofar as implicit modeling uses scalar fields. In another aspect, implicit modeling differs from CSG modeling insofar as implicit modeling has a richer vocabulary of operations than just Boolean operations (e.g., arbitrary mathematical expressions can be composed). Not being limited to Boolean operations allows, for example, for complex surfaces to be built. Not being limited to Boolean operations allows, as another example, for application of Unions and blends that are unlikely to fail. More generally, compared to CSG modeling implicit modeling is more robust, and allows for efficient representation of complex surfaces (e.g., lattices).

Conventional non-implicit CAD systems typically use surface intersections to go from a tree representation to topology (e.g., with such topology being stored using b-reps). However, conventional implicit CAD systems are typically not capable of going from a graph representation or tree representation to topology. In contrast, according to the approaches discussed herein an implicit CAD system and/or implicit kernel can go from a graph representation (or tree representation) to topology by use of the tracking functionality discussed herein.

As such the implicit CAD functionality discussed herein provides a multitude of benefits. As just some examples: a) implicit graphs (or trees) according to the functionality discussed herein are more robust than conventional graphs and trees (e.g., CSG trees); and b) tracking according to the functionality discussed herein is a more robust alternative to various conventional alternatives (e.g., surface intersections for extracting topology). More generally, the approaches discussed herein provide superior alternatives to, for instance, various capabilities of traditional CAD programs. As a further example benefit of the implicit CAD functionality discussed herein, provided, for an implicit body, can be an implicit graph (or tree) that includes the data (e.g., face data that points to geometry of an underlying plane) that can be provided by a non-implicit CAD system. As such, the functionality discussed herein allows for such data inclusion while still providing implicit CAD benefits (e.g., operations that are unlikely to break). As referenced above, implicit modeling can, in general, be unbreakable (e.g., implicit operations can be unlikely to break). In contrast, non-implicit modeling has a tendency towards breakage (e.g., non-implicit operations can be likely to break). In an aspect, non-implicit modeling has a tendency towards breakage because non-implicit CAD programs tend to use surface intersections to generate topology from a feature tree (e.g., CSG tree). Such use surface of intersections to generate topology lacks robustness. In contrast, the functionality discussed herein provides a robust alternative to using surface intersection for extracting topology.

According to various embodiments, the implicit functionality discussed herein can include providing a notebook UI to a user. The notebook can, from one point of view, bear certain visual similarity to a feature tree UI for a traditional non-implicit CAD program. The discussed tracking functionality can allow an implicit CAD system and/or implicit kernel to inspect the contents of an implicit body. In this way tracking can, for instance, provide linkage between the notebook UI and portions of a corresponding graph (or tree) for an implicit body. In contrast, conventional implicit approaches do not include the use of tracking, and consequently lack the ability to look inside implicit bodies. As such, conventional implicit approaches are limited to treating implicit bodies as black box functions. By permitting an implicit CAD system and/or an implicit kernel to look inside an implicit body, the tracking discussed herein allows implicit CAD to perform operations including those that are conventionally only available to non-implicit CAD, while still providing implicit CAD benefits (e.g., robustness).

According to certain embodiments the implicit CAD system and/or implicit kernel can, instead of using tracking, walk the tree of an implicit body and mirror the Boolean/blend operations on corresponding CAD primitives (e.g., on non-implicit CAD primitives) to produce the same geometry in CAD (e.g., in non-implicit CAD), such as for purposes of export from an implicit CAD system to a non-implicit CAD system.

However such an approach of not using tracking can tend to work on only simpler operations (e.g., such an approach can tend not to work if an implicit body contains difficult blends, morphs, and/or other more complex scalar field operations). Furthermore, where such an approach not using tracking is employed, the corresponding workflow can tend to fail to produce a CAD output for the various the reasons that Boolean operations tend to fail when traditional CAD approaches are employed. However, rather than walking the tree of an implicit body and converting the implicit graph (or tree) discussed herein into a series of brittle CAD operations that can fail because of surface intersections, the topology exposed by tracking can be used to construct a CAD body (e.g., for purposes of export from an implicit CAD system to a non-implicit CAD system).

By use of the various approaches discussed herein (e.g., the use of tracking), various benefits can accrue. For instance, use of the various approaches discussed herein can allow for successful interoperability between an implicit modeler and conventional non-implicit CAD. Such interoperability can, as just some examples: a) meet the needs of the industries beyond additive manufacturing (AM); b) successfully capture modeling intent; c) correctly capture features; and d) not feel alien to users compared to, say, a part produced using a traditional CAD system (e.g., a traditional non-implicit CAD system). It is observed, for instance, that approaches such as using non-uniform rational basis splines (NURBS) patches tend to not yield benefits including those just discussed.

Moreover, where the approaches discussed herein are used to achieve, for instance, effective interoperability between an implicit modeler and traditional non-implicit CAD, an implicit modeler can become (e.g., from a user perspective) functionally indistinguishable from a traditional non-implicit CAD system. Further, where the approaches discussed herein are used (e.g., where tracking is used), all (or nearly all) workflows that currently use conventional CAD (e.g., conventional non-implicit CAD) can switch to such an implicit modeler. Accordingly, implicit CAD can escape the current fate of typically being a limited use extension/tool that users (e.g., engineers) employ when they want to model complex geometry efficiently. Also, where the approaches discussed herein are used, implicit CAD can take on a position that is at least as prominent as traditional non-implicit CAD rather than, say, remaining a niche modeling technique that tries to survive next to traditional CAD (e.g., traditional non-implicit CAD). Further still, the approaches discussed herein (e.g., the discussed use of tracking) can be implemented as part of a CAD kernel (e.g., as part of an implicit CAD kernel) that can be superior to and more robust than existing CAD kernels, and that can be capable of supplanting existing CAD kernels. Application of the approaches discussed herein can allow implicit modeling to not be limited to being a niche modeling technique and has the potential to allow implicit modeling to supplant traditional CAD (e.g., traditional non-implicit CAD). As just an example, the capabilities of an implicit kernel implemented according to the approaches discussed herein can be a super set of the capabilities of traditional CAD kernels.

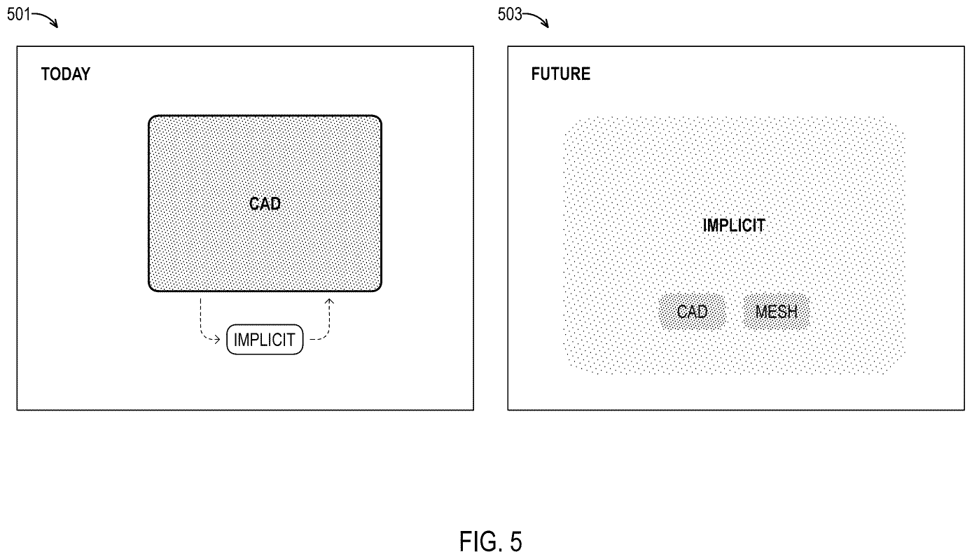

Turning to FIG. 5, shown leftward (501) is an example illustration of traditional CAD (e.g., traditional non-implicit CAD) being in a dominant/incumbent position relative to implicit modeling, with users dipping in and out of implicit modeling for niche workflows. Then, shown rightward (503) in FIG. 5 is, through implementation of the approaches discussed herein, implicit CAD supplanting traditional CAD while still, for instance, intaking traditional CAD bodies and/or meshes (e.g., to model implicit bodies). It is noted that intaking traditional CAD bodies and/or meshes to model implicit bodies can involve leveraging distance fields possessed by explicit geometry.

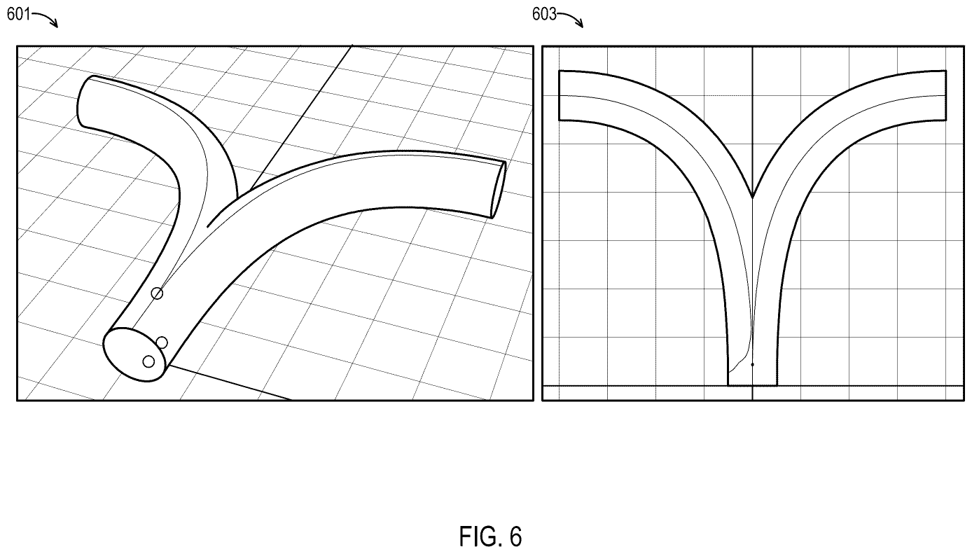

Discussed hereinabove in connection with FIG. 3 is the merging of two pipes into one. Further considering this merging, the example of FIG. 6 will now be considered. As depicted leftward (601) in FIG. 6, traditional non-implicit CAD is typically unable to perform the union. Then, applying the approaches discussed herein, tracking can identify three regions on the part: a) left pipe; b) right pipe; and c) a region where both pipes coincide. As depicted rightward (603), continuing with the example of FIG. 6, the boundary between the left pipe region and the right pipe region can be exported as a polyline to a non-implicit CAD program. Further according to the example of FIG. 6, curve projection can be performed in the non-implicit CAD program. Also in the non-implicit CAD program the input bodies can be trimmed and stitched back together. In this way, as depicted rightward in FIG. 6 by application of the approaches discussed herein a Boolean union and CAD output that can, as depicted leftward in FIG. 6, not be achieved using the traditional non-implicit CAD program can be achieved using the approaches discussed herein. Further, it is noted that the approaches discussed herein can also be used to achieve operations such as filleting that typically fail when using traditional CAD approaches. As such, employment of the approaches discussed herein (e.g., the tracking discussed herein) can allow for production of CAD output that cannot be achieved according to existing approaches.

As an example, the functionality discussed herein (e.g., the tracking functionality discussed herein) can be used in connection with meshing operations (e.g., generating meshes from implicit and/or non-implicit CAD bodies). Such meshing can utilize primitives having varying numbers of corners (e.g., three-corner primitives and/or four-corner primitives (quadramesh primitives) can be used). As another example, the functionality discussed herein can be used in connection with back to CAD operations (e.g., where export from an implicit CAD system to a non-implicit CAD system is performed).

The functionality discussed herein (e.g., the tracking functionality discussed herein) can, as another example, be used in connection with defining boundary constraints. For instance, as discussed hereinabove one or more boundary conditions can be defined on an implicit face, such as in support of simulation. As a further example, the functionality discussed herein (e.g., the tracking functionality discussed herein) can be used to provide CAD interactivity. For instance, tracking can be employed to allow a user to navigate from a region in the viewport to relevant parts of the notebook UI, and/or in providing linkage between the notebook UI and portions of a corresponding graph (or tree) for an implicit body. As an additional example, the functionality discussed herein can be used in connection with extracting feature curves for drafting, and/or for rounding edges (e.g., via fillet operations).

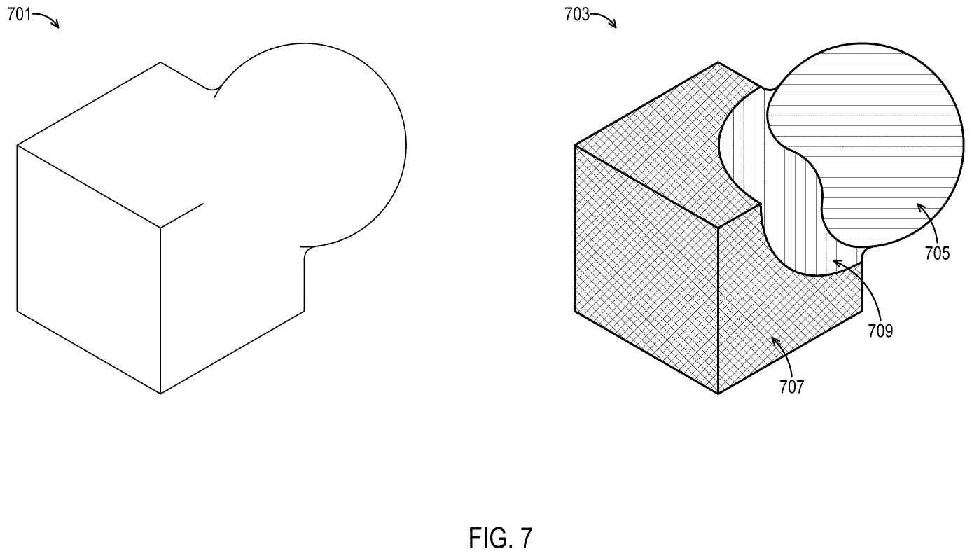

Turning to FIG. 7, as depicted leftward (701) according to conventional approaches implicit models return a raw spatial function with no information about the underlying data model. Then, as depicted rightward (703) in FIG. 7, according to the approaches discussed herein (e.g., as deployed via an improved implicit CAD kernel) feature history (e.g., all feature history) can be present in the implicit model at various points in space (e.g., at every point in space). Accordingly, as just an illustration, downstream blocks can know not only various field values (e.g., know the field value everywhere), but also the type of field being queried. For example, considering FIG. 7 rightward (703) according to the functionality discussed herein (e.g., using an implicit kernel implemented according to the functionality discussed herein) determination can be made for one or more of the depicted regions as to whether those regions came from a sphere 705, a cube 707, both a sphere and a cube (709), or from some other source(s).

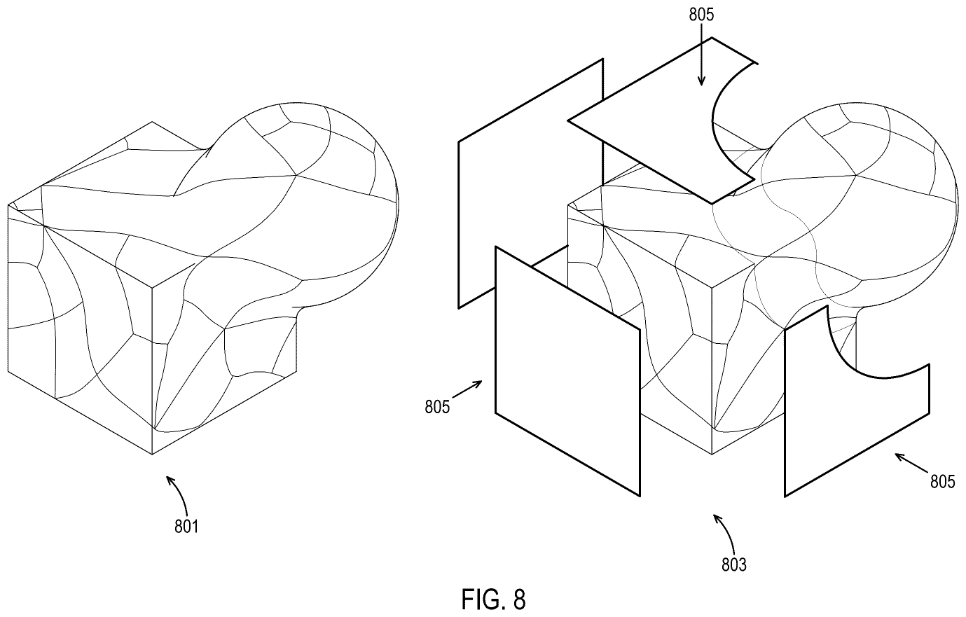

Turning to FIG. 8, as depicted leftward (801) because, according to conventional implementations, implicit models return raw spatial functions with no information about underlying data models, applied CAD approaches/algorithms are typically catch all solutions. As a result, compromises in robustness and/or CAD topology can arise. In contrast, as depicted rightward (803) in FIG. 8 according to the approaches discussed herein improved functionality can be experienced. In particular, where there is a model region having multiple features, and there is a multitude of CAD approaches/algorithms from which to select, the system can (e.g., via action of an implicit-to-CAD block thereof) select for one or more of the regions 805 (e.g., for each of the regions 805) an appropriate corresponding one of the approaches/algorithms. As a result, benefits including the ability to produce prismatic and/or analytical faces, along with preserved original faces, can accrue. Other, more ambiguous regions (e.g., blends), and/or simple, smaller pieces that are left over, can be handled, for instance, by using CAD patch solutions.

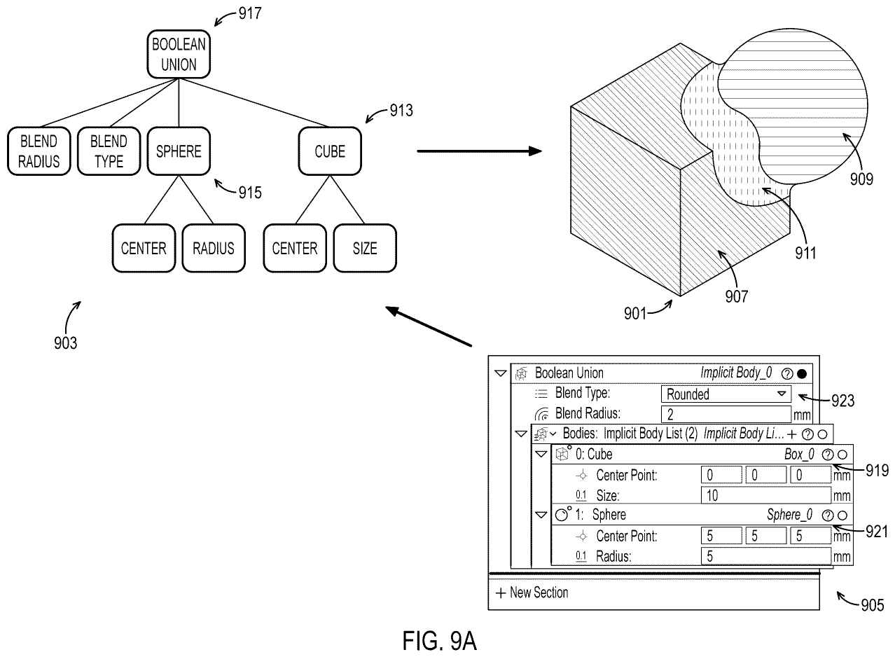

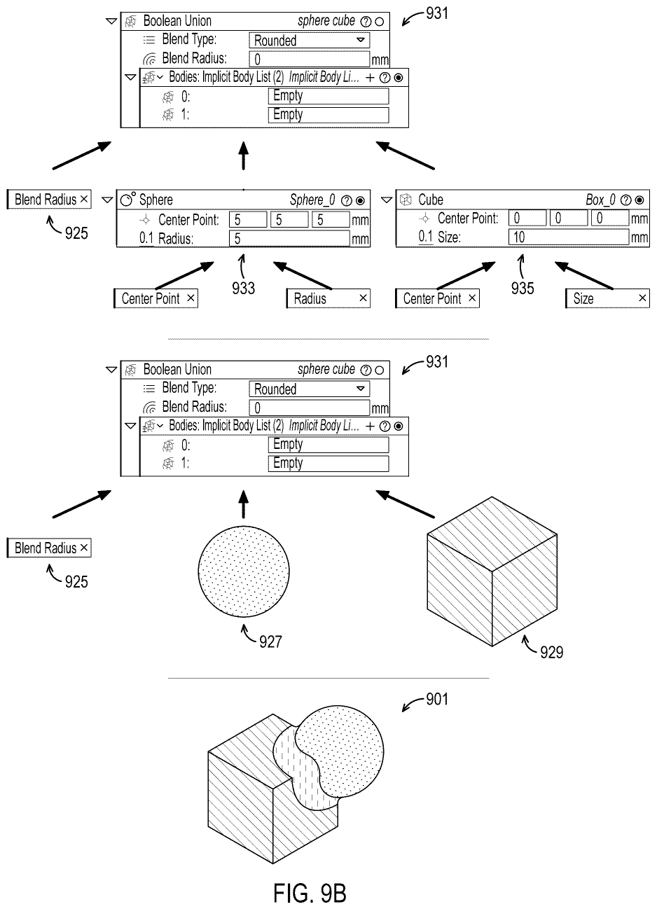

Turning to FIG. 9A, by application of the functionality discussed herein it is possible to trace results in an implicit body (e.g., an implicit body for a final model) back to their original implicits and corresponding parameters. Shown in FIG. 9A are implicit body 901, corresponding computational graph 903, and corresponding UI 905. The implicit body 901 includes implicit face 907, implicit face 909, and implicit face 911. Implicit face 907 can be traced back to cube node 913 in graph 903. Implicit face 909 can be traced back to sphere node 915 in graph 903. Implicit face 911 can be traced back to Boolean union/blend node 917 in graph 903. Also: a) implicit face 907 can be traced back to cube parameters 919; b) implicit face 909 can be traced back to sphere parameters 921; and c) implicit face 911 can be traced back to Boolean union/blend parameters 923. It is noted that various portions of the graph 903 can be referred to as subtrees. As just an illustration, graph 903 includes a three node subtree including node 915, and the two nodes depending therefrom.

Turning to FIG. 9B, shown is further detail regarding implicit body 901 of FIG. 9A. In FIG. 9B element 925 corresponds to the blend radius node of FIG. 9A, element 927 corresponds to sphere node 915 of FIG. 9A, and element 929 corresponds to cube node 913 of FIG. 9A. Further in FIG. 9B, UI 931 shows various parameters regarding Boolean union/blend node 917 of FIG. 9A. For example, UI 931 indicates that the Boolean union/blend of node 917 acts upon a sphere implicit body and a cube implicit body. As another example, UI 931 indicates a blend type of “Rounded.” Also shown in FIG. 9B are UI 933 showing various parameters regarding element 927, and UI 935 showing various parameters regarding element 929.

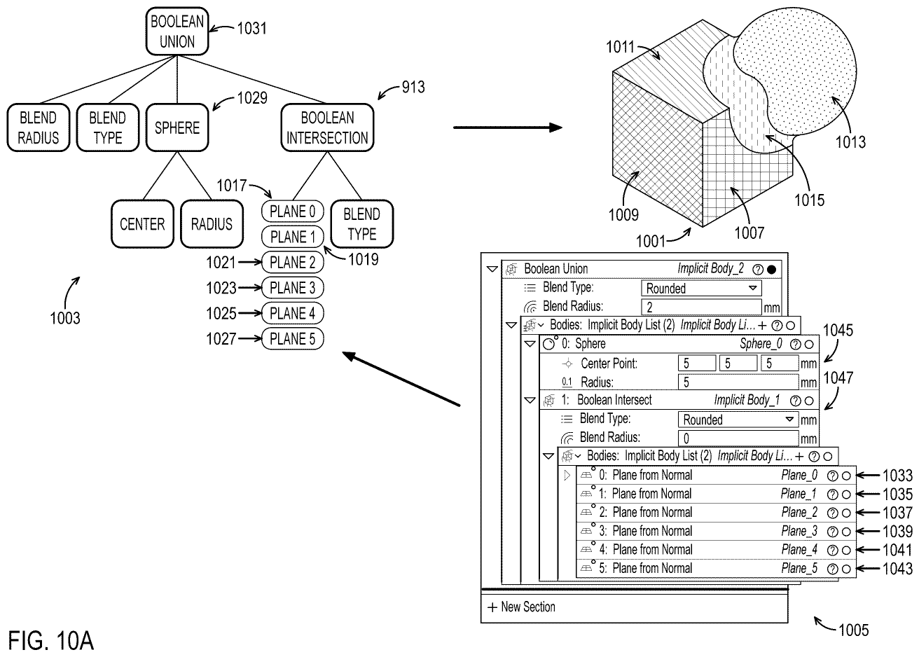

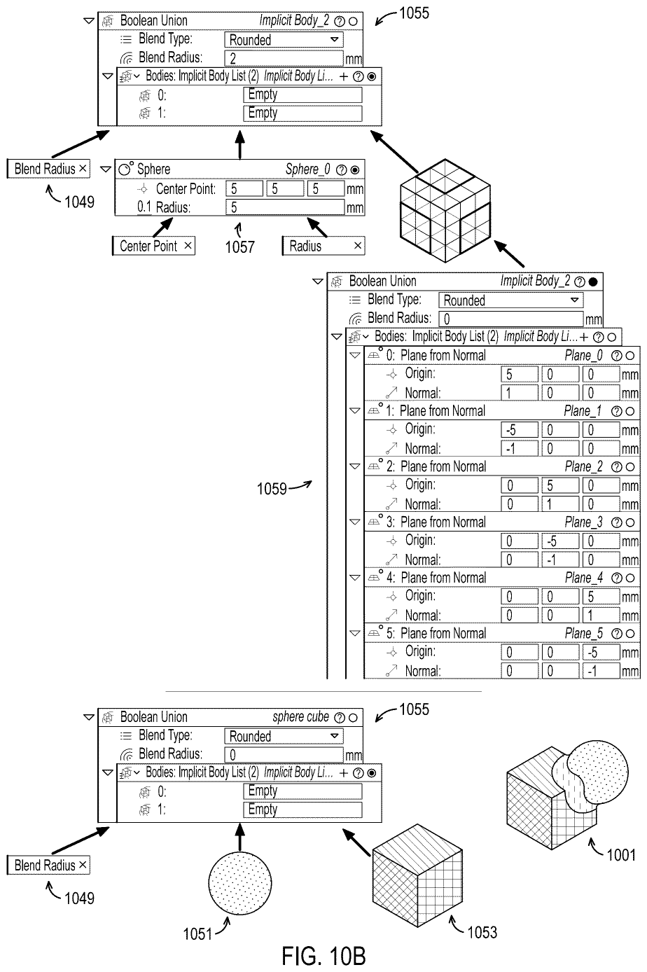

Turning to FIG. 10A, whether or not an implicit face resembles a conventional face can depend on how a corresponding implicit body is constructed. According to the discussed example of FIG. 9A, a cube portion of an implicit body was constructed using a cube primitive. Then, according to the example of FIG. 10A, a cube portion of an implicit body can instead be constructed using six planes.

Shown in FIG. 10A are implicit body 1001, corresponding computational graph 1003, and corresponding UI 1005. The implicit body 1001 includes implicit face 1007, implicit face 1009, implicit face 1011, implicit face 1013, and implicit face 1015. Not shown are three additional implicit faces corresponding to the three other cube faces. Implicit face 1011 can be traced back to plane node 1017 in graph 1003. Implicit face 1009 can be traced back to plane node 1019 in graph 1003. Implicit face 1007 can be traced back to plane node 1021 in graph 1003. Each of the three additional implicit faces can be traced back to a corresponding one of plane node 1023, plane node 1025, and plane node 1027. Then, implicit face 1013 can be traced back to sphere node 1029 in graph 1003. Additionally, implicit face 1015 can be traced back to Boolean union/blend node 1031 in graph 1003.

In some embodiments, the various nodes in graph 1003 can include colors or other indicia corresponding to similar colors or indicia of the various surfaces of implicit body 1001. For example, plane node 1017 may be colored a particular shade of green, and the same shade of green may be used to color implicit face 1011, demonstrating the correlation between node 1017 and face 1011. Similarly, the other plane nodes 1019, 1021, 1023, 1025, and 1027, the sphere node 1029, and the blend node 1031 all may include particular colors or other indicia in graph 1003, and the corresponding surfaces of the implicit body may be displayed with the same colors or indicia, explicitly illustrating how each surface of implicit body 1001 can be traced back to a particular node of graph 1003.

Also: a) implicit face 1011 can be traced back to plane parameters 1033; b) implicit face 1009 can be traced back to plane parameters 1035; c) implicit face 1007 can be traced back to plane parameters 1037; and d) each of the three implicit faces that are not shown can be traced back to a corresponding one of plane parameters 1039, plane parameters 1041, and plane parameters 1043. Further: a) implicit face 1013 can be traced back to sphere parameters 1045; and b) implicit face 1015 can be traced back to Boolean union/blend parameters 1047. It is noted that various portions of the graph 1003 can be referred to as subtrees. As just an illustration, graph 1003 includes an eight node subtree including a Boolean intersection node, a blend type node, and the six plane nodes 1017-1027 depending therefrom.

Turning to FIG. 10B, shown is further detail regarding implicit body 1001 of FIG. 10A. In FIG. 10B element 1049 corresponds to the blend radius node of FIG. 10A, element 1051 corresponds to sphere node 1029 of FIG. 10A, and element 1053 corresponds to the six plane nodes 1017-1027 that form the cube of FIG. 10A. Also in FIG. 10B, UI 1055 shows various parameters regarding Boolean union/blend node 1031 of FIG. 10A. For example, UI 1055 indicates that the Boolean union/blend of node 1031 acts upon a sphere implicit body, and upon a cube implicit body. This cube implicit body is formulated from implicit faces 1007-1011 and from the three implicit faces that are not shown in FIG. 10A. As another example, UI 1055 indicates a blend type of “Rounded.” Also shown in FIG. 10B are UI 1057 showing various parameters regarding sphere element 1051, and UI 1059 showing various parameters regarding implicit faces 1007-1011 and the three implicit faces that are not shown in FIG. 10A.

According to various embodiments, an improved implicit CAD kernel that uses ASGs can be implemented. An example workflow using this improved kernel can include one or more of the following stages:
1) An object (e.g., an implicit or a transform) can be constructed as an ASG.
2) The object can be compiled into a bytecode representation.
3) An interpreter can evaluate the bytecode. According to certain embodiments there can be multiple interpreters, and each of these multiple interpreters can be specialized to work, for instance, with a given one of: a) values (e.g., scalars and/or ints); b) intervals; and/or c) batches of values. According to other embodiments, a monolithic interpreter can be used.
4) The interpreter can evaluate the bytecode at a particular point, region, or batch of points.

An ASG can, in various embodiments, be compiled into a further form (e.g., into GLSL code) for evaluation on a GPU. The improved implicit CAD kernel can, in an aspect, provide a framework for storing, transforming, and/or evaluating functions from Rⁿ to R^{m}. An example use case is to manipulate implicit functions, for instance implicit functions that map: a) from real coordinate 3D space (R³) to real line space (R); and/or from real coordinate plane space (R²) to R. Further, functionality (e.g., a library) can be provided for constructing arbitrary implicit functions that can be, for instance, efficiently meshed, sphere traced, and/or sliced. Also, functionality can be provided for representing arbitrary functions from Rⁿ to R^{m} in order to be usable for additional purposes (e.g., for design optimization). Various aspects (e.g., the ASG, the bytecode, the interpreter, and the compiler) and their interrelationships will now be discussed in greater detail.

An ASG can, in an aspect, be a directed acyclic graph (DAG) that conveys a computation. Each node in the ASG can represent an expression. For instance, each node can represent the computation of a value using the values associated with its children. For example, a node can represent the addition of two scalar values associated with its child nodes. An ASG can represent the semantics of a relevant computation while using no human readable syntax.

An ASG need not be evaluated directly. Instead, an ASG can represent an abstract computation. Prior to evaluation according to the functionality discussed herein, an ASG is typically compiled into a secondary form (e.g., into bytecode and/or machine-code) that can be, as just some examples, interpreted and/or executed directly on hardware. Further, an ASG need not specify all necessary details of a computation. For instance, an ASG need not dictate whether or not a scalar value should ultimately be represented using floating point.

An ASG can act as a software developer interface for creating implicits and other evaluable objects such as transformations. As such, the nodes of an ASG can represent different types of values (e.g., not just scalars). Also, the type of the root node of an ASG can determine the type of object that the ASG represents.

According to some embodiments, a tree can be used in place of an ASG. However, according to other embodiments it can be considered preferable to use an ASG. When designing a computation, it can sometimes be useful to reuse a node multiple times (e.g., such that it has multiple parents). The use of an ASG instead of a tree can be beneficial for circumstances including this. While it can be possible to, when using a tree, duplicate a node for each reuse, doing so typically calls for a conscious effort and/or risks destroying useful information (e.g., knowing that the duplicate nodes are equivalent) without providing a clear benefit in return.

Value types supported by the improved implicit kernel discussed herein can, as just some examples, include scalars, Booleans, integers, 2D vectors, 3D vectors, and matrices. The improved implicit CAD kernel discussed herein can support value types so as to leverage the capabilities of GLSL. Doing so can allow the improved kernel to take full advantage of GPU capabilities. For instance, GLSL supports up to 4×4 matrices and their corresponding arithmetic. As such, the improved kernel can be implemented so as to support up to 4D vector and/or 4×4 matrix value types.

Further still, the improved kernel can be implemented so as to support fixed-size arrays as values (e.g., as an alternative to N-dimensional vectors). Also, the improved kernel can be implemented so as to support bounded-size arrays (i.e., fixed-capacity arrays with variable sizes). Bounded-size arrays can be useful, for instance, when processing a bounded but unknown amount of data. As just an illustration, some maps can have multiple inverses, and it can be desired to provide a capacity to compute and/or process such multiple inverses. Additionally, the improved kernel can be implemented so as to support interval values. Such support of internal values can yield benefits including but not limited to facilitating support of interval evaluation on the GPU.

Also, various embodiments can include conversion (e.g., automatic conversion) of scalar-valued ASGs into their corresponding interval-valued ASGs. Here it is noted that supporting interval-valued ASG nodes can be orthogonal to supporting interval evaluation, interval evaluation being typically handled at the interpreter level rather than at the ASG level.

Turning to conditional nodes, a conditional node can have three inputs: a condition node that outputs a Boolean, and two other nodes that output the same type of value. The condition node can be evaluated, and then one of the other two nodes can be selected as output, based on the result of the condition. When performing an interval evaluation, it can be the case that the condition node evaluates to either true or false within the evaluated region. Under this circumstance, both of the other child nodes are typically evaluated and combined to yield the output.

As to transformation nodes, a transformation node can be used to represent a transformation (e.g. an affine transformation) of a point, a vector, and/or another transformation (e.g., another affine transformation). As just an illustration, a matrix and a point can be taken as input, and a new point can be generated as output. In various embodiments, rotation nodes, translation nodes, and/or scaling nodes can be implemented. Such an implementation can yield benefits including but not limited to facilitating reasoning about intent (e.g., facilitating reasoning more effectively than through use of a general matrix).

Considering arbitrary variables, some ASG nodes can represent arbitrary variable values that can be assigned, for instance, at interpretation time rather than at compile time. This functionality can be useful, for example, where it is desired to make changes (e.g., small changes) to an object on-the-fly without having to recompile the ASG. Such an arbitrary variable node can be assigned a unique identifier that is carried into, for instance, the bytecode and/or into the GLSL code. According to various embodiments, after an interpreter has been instantiated, corresponding variable values can be assigned.

Turning to differentiation, one approach that can be used to provide gradients is backward mode automatic differentiation (AD). However, one downside of using backward mode AD is that, generally speaking, it cannot be used to provide a gradient block. Such holds because backward mode AD typically only provides a different way of evaluating a given tree. Accordingly, it is not easily possible to determine higher order gradients with backward mode AD. A further downside of backward mode AD is that it typically calls for evaluating oracles twice (e.g., once in the forward pass and once in the backward pass). It is noted that AD can be used, for instance, optimizing various parameters of a design (e.g., in minimizing one or more thicknesses and/or weights).

Further regarding differentiation, another approach that can be used to provide gradients is symbolic differentiation. One downside to using symbolic differentiation is that trees tend to get very large very quickly. A second downside to using symbolic differentiation is that in implementations where only scalars are supported, determining the gradient with respect to standard (x, y, z) coordinates typically calls for evaluating the tree (including any oracles) three times.

As such, according to various embodiments an ASG transformation that represents forward mode AD can be used. One advantage of using forward mode AD is that operations can be evaluated only once. Another advantage of using forward mode AD is that by implementing representation of vector types the problem of evaluating oracles and/or nodes multiple times can be avoided. According to an implementation, forward mode AD can be represented on the ASG level. Where such an implementation is used, composition can, in various embodiments, involve applying a given transformation (e.g., Mul) to a node representing a result of a forward mode AD computation.

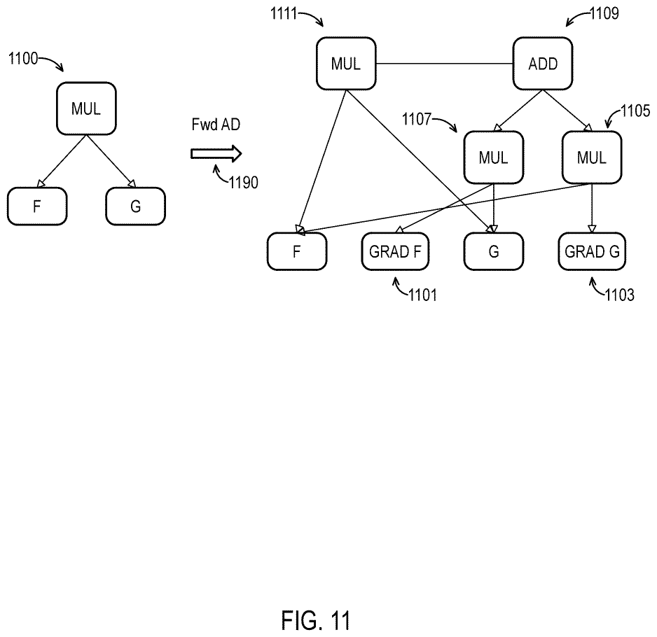

Turning to FIG. 11, shown is an example of using forward mode AD on the ASG level, as discussed. According to the example of FIG. 11, the noted forward mode AD 1190 is applied to mul(f, g) 1100. As depicted by the figure performance of the forward mode AD can include performing grad(f) 1101 and grad(g) 1103. As also depicted by the figure, performance of the forward mode AD can include performing a mul( ) 1105 on f and the result of 1103, and performing a mul( ) 1107 on the result of 1101 and g. As further depicted by the figure, performance of the forward mode AD can include performing an add( ) 1109 on the result of 1107 and the result of 1105. As also depicted by the figure, performance of the forward mode AD can include performing a mul( ) 1111 on f and g.

Turning to ASG architecture, according to various embodiments, various ASG types of nodes (e.g., every type of node) can be implemented as its own class. Each such class can inherit from a common base AsgNode class. Each such node class can specify one or more of: a) the type of object that it produces; b) the number of input nodes it utilizes; and c) the types of objects that its children produce. The input and output type information can be encoded in the class (e.g., using templates). In this way, the compiler (e.g., C++ compiler) can prevent compilation of malformed ASGs.

A given ASG node can, in various embodiments, know the function name of its corresponding GLSL code (e.g., to enable GPU acceleration), and/or can indicate that it does not support GLSL. Additionally, in various embodiments a given ASG node can know how to generate its corresponding bytecode instructions. As just an illustration, such an ASG node might not know the details of how the bytecode is encoded, and instead can act to generate a corresponding interface.

In various embodiments, ASG optimization can be performed. As just some examples, common subexpression elimination (CSE) and/or constant folding can be used (e.g., in connection with a non-ASG representation such, as static single assignment (SSA)-based bytecode).

According to various embodiments, register-based bytecode and a corresponding interpreter can be used. According to other embodiments, a tree-walking interpreter or graph-walking interpreter can be used. Where such a tree/graph-walking interpreter is used, implementation of evaluation for an ASG can include implementing an evaluate method for each node type. The evaluate method can: a) recursively call the evaluate methods of its inputs; b) compute the output value using the results from the input evaluations; and c) return the resulting output value. While the tree-walking and bytecode approaches are both viable, at least under certain circumstances the bytecode approach can be preferred. The tree-walking and bytecode approaches will now be compared with respect to various aspects.

Turning to computation source tracking, such is typically not possible when using the tree-walking approach, but is possible when using the bytecode approach. On the topic of maintainability, when the tree-walking approach is used, creating a new ASG node typically implies implementing low level computation details. When the bytecode approach is used, creating a new ASG node, in general, implies generating bytecode (intermediate level computation details). Further on the topic of maintainability, when the tree-walking approach is used the evaluation interface is typically tightly coupled to implementation. When the bytecode approach is used, the evaluation interface is typically decoupled from implementation. Also on the topic of maintainability, when the tree-walking approach is used low level details cannot, generally speaking, easily be changed. This is because the low-level details are typically spread through all ASG nodes. For example, one cannot easily add a just-in-time (JIT) compiler subsequent to an initial deployment, because one would need to implement JIT for all ASG nodes. Here it is noted that one can generally expect to have many more ASG nodes than bytecode instructions. When the bytecode approach is used, low level details can easily be changed because they are localized to the interpreter. For example, one can easily add a JIT compiler subsequent to an initial deployment, because one would only need to implement JIT for each bytecode instruction. Here it is noted that one can generally expect to have many fewer bytecode instructions than ASG nodes.

On the topic of optimization, when the tree-walking approach is used an ASG node can have multiple parents. As such, when naively evaluating an ASG a node can be evaluated multiple times. According to various embodiments, in an attempt to overcome this phenomenon cached computed results can be used. However, this typically implies that an ASG node is able to recognize when it has already computed some result. If such a result is stored in the ASG node itself, then multiple threads can, generally speaking, not be able to safely evaluate an ASG simultaneously, because each thread will typically need its own cache. If the results are stored in an external structure, there will typically be call that implemented registers be passed through an ASG during evaluation. When the bytecode approach is used, the phenomenon of call to evaluate an ASG node multiple times can still occur. However, the phenomenon can more naturally be addressed when using a bytecode interpreter rather than in a tree-walking interpreter, because included among approaches for addressing the phenomenon include approaches that involve creating a register-like structure separate from the ASG.

Also on the topic of optimization, when the tree-walking approach is used optimizations are typically baked into the ASG implementation. When the bytecode approach is used, advantage can be taken of it being the case that bytecode can be an intermediate representation in SSA form, which can be useful for several optimizations. These optimizations can easily be toggled on and off based on needs. Further, such optimizations can easily be added subsequent to an initial deployment without editing the ASG nodes.

Using a bytecode interpreter can provide benefits including enabling the noted source tracking. Source tracking can provide, for instance, for implementation of features such as node selection for interactivity. Further, source tracking can provide for the implementation of subgraph pruning. The bytecode interpreter can facilitate source tracking given, for instance, that source tracking keeps track of the flow of data through various computations (e.g., all computations), including low-level computations. An ASG node, from one viewpoint, represents a high-level computation, with the low-level computations that happen while evaluating a node being typically lost where corrective action is not taken. In contrast, the proposed bytecode design discussed herein can operate at a low level, and can have the registers to store the results from each of the low-level computations.

The use of a bytecode layer can also improve maintainability of the implicit kernel (e.g., in a way that outweighs any increased maintainability load arising from the addition of extra components to provide the bytecode layer). In an aspect, the bytecode can act as an abstraction layer over low-level computation, thereby, for instance, removing call for the ASG nodes to deal directly with low level (e.g., the lowest level) details. Here, the nodes can emit a single stream of bytecode, instead of there being call that nodes implement multiple different functions for evaluating: a) values; b) intervals of values; and c) batches of values and/or of intervals of values, each likely loaded with extra logic for optimizations such as subgraph pruning.

Such can be important given at least that there are typically more ASG nodes (e.g., many more ASG nodes) than bytecode instructions. As such, the low-level details can be handled by the few instructions rather than by the many ASG nodes. Further, the bytecode abstraction layer can beneficially make it easier to modify low-level details in the future. For example, such a modification can include speeding up the evaluation of pure implicits. Here, such speedup can include evaluating the pure implicits in machine code. Using the bytecode approach discussed herein, implementation can include swapping an interpreter/evaluator component of the implicit kernel for a JIT compiler of the bytecode, without, say, call to modify the ASG.

According to some embodiments, stack-based bytecode can be used. According to other embodiments, register-based bytecode can be used. At least under certain circumstances, using register-based bytecode can be preferred. For example, certain features can be implemented that call for computed values to persist, such as in order to analyze the flow of data throughout an entire computation. One such feature is a source tracking feature. Under circumstances such as these, where register-based bytecode is used computed values that are to persist can persist in register memory. As another example, there can be call for computed values to persist where they are to be reused. Here also register-based bytecode can be preferred, since where stack-based bytecode is used, the corresponding stack-based interpreter would typically pop and discard a value once it is used in an operation. According to various embodiments, an interpreter-based approach can be used. According to other embodiments, an approach that includes JIT compilation to machine code can be used.

On one hand, an interpreter can impose a performance penalty (e.g., a significant performance penalty) over directly executing equivalent machine code. As such, JIT compilation of the bytecode into machine code can be beneficial for various implementations. On the other hand, for implementations where, say, execution time is typically dominated by oracles (or other similar functionalities) that do not benefit from JIT compilation, implementation can opt to use an interpreter-based approach.

Still, where a decision is made to use an interpreter-based approach instead of a JIT compilation approach, implementation of the bytecode interpreter framework can be such that it is possible to swap in a JIT compiler in the future (e.g., by swapping an interpreter/evaluation component of the implicit kernel). Also, in various embodiments where an interpreter-based approach is used, batched evaluation can be employed to amortize the interpreter's overhead. Avoidance of verification during execution can, in various embodiments, be implemented. As just an illustration, the correctness of an ASG can be verified either during compilation of C++ code (or other employed high level language code), or during ASG-to-bytecode compilation. In this way, benefits including being able to skip various (e.g., most) runtime safety checks (e.g., type checks) during interpreter execution can be reaped.

According to various embodiments, bytecode that uses RISC-like instructions can be used. According to other embodiments, bytecode that uses CISC-like instructions can be used. Here, a bytecode whose instructions only (or typically only) operate on low-level values (e.g., scalar, int, and/or bool) can be referred to as RISC-like. Further here, a bytecode whose instructions can operate on high level values (e.g., vec3 and/or mat4) can be referred to as CISC-like. On one hand, RISC-like can be easier to maintain and/or vectorize. On the other hand, CISC-like can provide benefits such as reducing interpreter overhead and/or maintaining high-level design intent. At least under certain circumstances, where implementors find difficulty between choosing RISC-like instructions or CISC-like instructions, there can be wisdom in selecting RISC-like instructions as moving from RISC-like to CISC-like can be easier than moving from CISC-like to RISC-like.

Turning to bytecode encoding, one possible bytecode encoding is to store a list of instruction objects. Here, an instruction object can be an instantiation of some instruction class that represents a specific type of instruction. As just an illustration, there can be an AddScalars instruction that implements a method that reads two scalars from registers then adds them and stores the result in another register. A given instruction class can, for instance, implement three such methods: a) a method to evaluate single values; b) a method to evaluate intervals; and c) a method to evaluate batches of values. A second possible bytecode encoding can be a compact encoding of instructions into an array of bytes. This approach can potentially be more complex to implement. But, it can have potential benefit to performance of bytecode generation and/or execution.

According to various embodiments, the mode of evaluation used by the interpreter can be one point at a time. That is, given one point, the interpreter can output one scalar if it is evaluating an implicit, or a point or vector if it is evaluating a transformation. On one hand, the use of a single point interpreter can arguably result in increased overhead compared to, for instance, an equivalent evaluation with machine code running directly on hardware. However, on the other hand, in many cases such possibly increased overhead has the potential to not to be appreciable, because various functionalities (e.g., oracles) can be expected to dominate execution time. Nevertheless, the use of a single point interpreter and the use of machine code running directly on hardware are both considered viable possibilities.

A single bytecode can, according to various embodiments, support interval evaluation and/or batched evaluation, in addition to single point evaluation. An interval evaluator can, as just an illustration, take as input an axis-aligned box that represents the region of space to be evaluated, and output an interval (e.g., min and max scalar values) that contains various values that can be obtained from evaluations within a given region (e.g., all values that can possibly be obtained from evaluations within the region). In various embodiments the output of the interval evaluator can be guaranteed (e.g., the interval evaluator can guarantee that it contains all values that can possibly be obtained from evaluations within the region). If the object being evaluated is a transformation (or other operation that typically outputs points and/or vectors), then the corresponding interval evaluation can output, for instance, a 3D interval that represents possible values in each dimension.

From one point of view, to guarantee 100% correct (or nearly 100% correct) interval evaluation, floating point rounding modes are to be taken into account. However, various functionalities (e.g., oracles) do not typically use rounding modes. As such, according to the noted point of view, an ASG with such a functionality cannot necessarily be guaranteed to give completely correct intervals. On the other hand, rounding modes appear to be unlikely to be relevant in practice. Further, changing rounding modes can have the potential to result in a performance penalty (e.g., a significant performance penalty). As such, according to various embodiments the issue of rounding modes can be ignored.

Batched evaluation can, according to various embodiments, be performed. Batched evaluation can provide for the evaluation of multiple points with a single call to the interpreter. Here, executing a single bytecode instruction on a batch can be equivalent to executing the bytecode instruction on every value in the batch. As a result, various performance gains (e.g., compared to performing the single point evaluations individually) can be experienced. As just some examples, these performance gains can arise because: a) the interpreter overhead is reduced due to only one instruction being processed per batch; and/or b) various operations can be vectorized such that multiple points are processed at the same time. In various embodiments, batched interval evaluation can be implemented. Such implementation can include adding a fourth method to the instruction classes. An ultra-batched evaluation that is run on the GPU can, in various embodiments, be performed.

Evaluation source determination can, according to various embodiments, be performed. When evaluating a point (or an interval) determination can be performed, for various instructions (e.g., for each instruction), as to which inputs are the source of the output. In some cases, all inputs can be considered to be the source of the output. For example, when adding two numbers to evaluate 3+4, the output 7 can be considered to rely equally on both inputs. However, if, say, one of the inputs were 0 such that 3+0 was being evaluated, then the output 3 can be considered a copy of the left input, such that the left input can be considered the source.

Source determination can allow the system to ascertain where an output value originates from. In some cases, an output value can have a long history when traced back to its first appearance (e.g., when evaluating many Boolean unions and/or intersections). Determining the original source of an output can be useful for a multitude of circumstances. As just some examples, determining the original source of an output can be useful for: a) selecting objects for interactivity; and b) determining whether a value is due to a mesh (or due to a CAD face), or due to an intermediate operation (e.g., a Boolean blend).

Subgraph pruning can, in various embodiments, be performed. Interval evaluation can be used to support subgraph pruning. Subgraph pruning data can be updated while running an interval evaluation. Still, the update of subgraph pruning data during interval evaluation can be toggled off (e.g., at compile time) if it is not needed. Subgraph pruning data can be obtained from the source tracking data of an interval evaluation. Indeed, the source tracking data can be viewed as a more general form of the subgraph pruning data. This view can be taken at least because the source tracking data allows for pruning of low-level instructions (e.g., pieces of ASG nodes) rather than only allowing for pruning of high-level ASG nodes. subgraph pruning can, in an aspect, operate on the principal that, if the output of an instruction comes from (e.g., entirely from) a single input (source), then, if there are other inputs, they are not contributing any useful information, and can be pruned. Three approaches for implementing subgraph pruning will now be discussed. It is noted that performance of these approaches can be preceded by obtaining the prune data.

According to the first approach, the ASG can be recompiled into a new, shorter bytecode by not compiling pruned instructions. The new bytecode takes less time to generate and to execute than the original bytecode. Benefits of the first approach include that it is straightforward to implement, and that it can provide significant performance improvements for at least some algorithms, despite the call to recompile the bytecode. It is noted that the first approach can typically be used in conjunction with a bytecode generator (e.g., a quick bytecode generator).

According to the second approach, the ASG can be modified by inserting conditional nodes therein. The conditional nodes can be able to read the prune data so as to skip evaluation of pruned graph portions (e.g., subgraphs). Advantages of the second approach include the ability to allow for pruning without recompilation. Pruning without recompilation is possible at least because the conditional nodes are part of the ASG. It is observed that, because the conditional nodes are part of the ASG, the conditional nodes are typically evaluated also when no pruning occurs. In embodiments where GPU-executable code (e.g., GLSL) is generated (e.g., directly generated) from the ASG, the second approach can allow the GPU to take advantage of subgraph pruning without having to recompile a relevant entity (e.g., a shader).

According to the third approach, the bytecode is not recompiled and the ASG is not modified. Instead, the interpreter uses the prune data and/or the source tracking data to: a) skip over unnecessary instructions; and/or b) ensure that instructions output the correct value when it is known that the value comes from a single source. Advantages of the third approach include the interpreter being able to skip (e.g., quickly skip) subgraphs (e.g., entire subgraphs) of instructions without there being call to recompile the bytecode. Where the interpreter is built in GLSL, the third approach can lead to improved GPU evaluation.

It is noted that, according to various embodiments, capabilities of the implicit kernel can include one or more of: a) support for oracles; b) support for gradient evaluation; c) support for Lipschitz-based interval evaluation; d) single instruction multiple data (SIMD) advanced vector extensions (AVX) fallback for CPUs that do not have AVX; and e) support for serialization. Also, capabilities of the implicit kernel can include support for various forms of interactivity. As just an example, vars (e.g., vars that can be set by a user via a UI) can be configured so that they can be passed to one or more shaders (or other entities). For instance, the vars can be configured as GLSL uniforms. As another example, vars can be connected to various UI elements (e.g., sliders) to allow the vars to be set by a user. A Kratos UI can, as just an illustration, be used.

Further still, capabilities of the implicit kernel can include support for allowing interval values to be used as ASG node outputs. As just some examples, implementation of such functionality can provide for: a) simplifying the generation of interval evaluations in GLSL; b) batched evaluation of intervals without extra interpreter work; and/or c) deduplication of interval property tracking code and reuse of property tracking code for scalars. Also, in various embodiments certain functionality (e.g., slicing and/or meshing functionality) can be provided by interfacing the implicit kernel with a further kernel. Such interfacing can include converting a graph (or tree) of the implicit kernel into a graph (or tree) of the further kernel (e.g., by action of an oracle of the implicit kernel and/or an oracle of the further kernel). Benefits of this interfacing approach include backwards compatibility.

Shown below is pseudocode corresponding to various functionality of the discussed implicit kernel that uses ASGs:

```
  struct PrimitiveType
  {
    enum Primitive
    {
    Bool, Int, Scalar
    };
  Primitive primitive;
  int rows = 1, columns = 1;
    };
  class AsgNode {
  public:
  // child interface to navigate the tree.
    virtual int childCount( );
    virtual AsgNode child(int i);
  // make a copy of a node, but instead of using the current children
  // the new node will have the provided children as inputs.
    virtual AsgNode copyShallow(vector<AsgNode> children);
    virtual RegisterSet compileBytecode(CompilerContext context);
    virtual string getGLSL( );
  private:
    PrimitiveType primitiveType;
  }
  // implement child interface for some common number of children
    class NullaryNode : public AsgNode { .. }
    class UnaryNode : public AsgNode { .. }
    class BinaryNode : public AsgNode { .. }
    class Instruction {
    public:
    void run(Interpreter interpreter);
    void runInterval(IntervalInterpreter interpreter);
    void runBatch(BatchInterpreter interpreter);
  }
  // Info for constructing a value from registers.
  // If type checking when getting an interpreter output not desired,
  // then this can be replaced by an int in the Bytecode class.
  class ValueRef {
    ValueType valueType;
    int startIndex;
  }
  enum ValueType { Scalar, Bool, Int, Vec3, ... }
  // The bytecode contains a list of instructions and a set of registers
  // which contain the result of the computation once the bytecode is run
  // to completion.
  class Bytecode {
    vector<unique_ptr<Instruction>> instructions;
    ValueRef outputRef;
  }
  class CompilerContext {
    Bytecode code;
    // Bookkeeping to do common subexpression
    // elimination and register assignment.
  ..
  }
  class BaseInterpreter {
    InstructionStream& stream;
    int instructionPointer = 0;
    BaseInterpreter(InstructionStream& stream) : stream(stream) { }
  }
  class Interpreter : public BaseInterpreter {
    vector<Scalar> scalarRegisters;
    vector<Bool> boolRegisters;
    vector<Int> intRegisters;
    vector<Scalar> scalarVariables;
    vector<Bool> boolVariables;
    vector<Int> intVariables;
    Bytecode(Bytecode code) { super(code); /*Make space for registers and
variables*/ }
    // step automatically increments the instructionPointer.
    // Some instructions (ex: branches) also adjust instructionPointer.
    void step( ) { code.instructions[instructionPointer++].run(this); }
    void run(Vec3 xyz) {
      scalarVariables[0] = xyz.x;
      scalarVariables[1] = xyz.y;
      scalarVariables[2] = xyz.z;
      while(instructionPointer < code.instructions.length) step( );
    }
    // Optional functions for retrieving intermediate results.
    Scalar& operator[ ](int i) { return scalarRegisters[i]; }
    // The array access operator is extendable to
    // cover more primitive types.
    // Scalar& getScalar(int i) { return scalarRegisters[i]; }
    // Bool getBool(int i) {...}
    // Int getInt(int i) {...}
    // Functions for retrieving the final result.
    Scalar outputScalar( ) {
    assert(code.outputRef.valueType == Scalar);
    return getScalar(code.outputRef.startIndex);
    }
    Vec3 outputVec3( ) {...}
  ...
    }
    getVec3(Interpreter, RegisterSet registers) -> Interpreter::Vec3 { ..
}
    class IntervalInterpreter extends BaseInterpreter {...}
    class BatchInterpreter extends BaseInterpreter {...}
  //===============================================================
  /* Example nodes */
  template<class T>
  class Const<T> : public NullaryNode {
    T value;
    void compileBytecode(CompilerContext context) {...}
    string getGLSL( ) {...}
  }
  class Add : public BinaryNode {
    AsgNode lhs, rhs;
    RegisterSet compileBytecode(CompilerContext context) {...}
    string getGLSL( ) {...}
  }
  //===============================================================
  /* Example instructions */
    class AddInstruction : public Instruction {
    int out, lhs, rhs;
    void run(Interpreter interpreter) {
      auto reg = interpreter.scalarRegisters;
      reg[out] = reg[lhs] + reg[rhs];
    }
    void runInterval(IntervalInterpreter interpreter) {
    var reg = interpreter.scalarIntervalRegisters;
    reg[out] = reg[lhs] + reg[rhs];
    }
  void runBatch(BatchInterpreter interpreter) {
    auto reg = interpreter.scalarBatchRegisters;
    reg[out] = reg[lhs] + reg[rhs];
    }
  }
```

Shown below is further pseudocode corresponding to various functionality of the discussed implicit kernel that uses ASGs:

```
  //===============================================================
  /* Example class-based architecture Also possible is a trye bytecode */
  enum Instruction is Byte {
    Add, Sub, Mul, ...
  }
  class Bytecode {
    List<Byte> bytes;
    List<Scalar> scalarConstants;
    List<bool> boolConstants;
    List<int> intConstants;
  }
  class CompilerContext {
  }
  // Use ScalarType, BoolType, and IntType to operate on either values,
intervals, or batches.
  // To ensure type consistency, one type can be set and the others
inferred
    class Interpreter<ScalarType, BoolType, IntType> {
    List<ScalarType> scalarRegisters;
    List<BoolType> boolRegisters;
    List<IntType> intRegisters;
    Bytecode code;
    int instructionPointer;
    List<Scalar> scalarVariables;
    List<Bool> boolVariables;
    List<Int> intVariables;
    Byte eatByte( ) { return code.bytes[instructionPointer++]; }
    Byte getByte( ) { return code.bytes[instructionPointer]; }
    Short eatShort( ) {
      var val=((List<Short>)code.bytes)[instructionPointer];
instructionPointer+=2; return val;
    }
    Short getShort( ) { return
((List<Short>)code.bytes)[instructionPointer]; }
    Int eatInt( ) { ... }
    Int getInt( ) { ... }
    Scalar eatScalar( ) { ... }
    Scalar getScalar( ) { ... }
  constructor(Bytecode code) { /*Make space for registers and variables.
Store bytecode.*/ }
  void step( ) {
    Instruction instruction = code.bytes[instructionPointer++] as
Instruction;
    switch (instruction) {
    case AddScalars:
      scalarRegisters[eatShort( )] = scalarRegisters[eatShort( )] +
scalarRegisters[eatShort( )];
    case MinScalars:
      scalarRegisters[eatShort( )] = min(scalarRegisters[eatShort( )],
scalarRegisters[eatShort( )]);
    case ConstScalar:
      Short regIdx = eatShort;
      if (ScalarType is Scalar)
        scalarRegisters[regIdx] = code.scalarConstants[eatShort( )];
      else if (ScalarType is Interval<Scalar>) {
      Scalar c = code.scalarConstants[eatShort( )];
      scalarRegisters[regIdx] = Interval<Scalar>(c, c);
      }
      else if (ScalarType is Batch<Scalar>) {
      Scalar c = code.scalarConstants[eatShort( )];
      scalarRegisters[regIdx] = makeFilledBatch(c);
      }
    ...
    }
    }
  }
```

Further to the use of ASGs, in various embodiments the implicit CAD kernel can be implemented so as to use abstract syntax trees (ASTs). A mathematical function can be represented symbolically as an AST, where each node in the tree corresponds to an operation on set of data types (e.g., a set of built-in data types). An AST can, as just an illustration, be implemented using a class hierarchy. In this class hierarchy, operations (e.g., every operation) can inherit from an abstract object called AstNode. Among the methods to be implemented for the AstNode interface can be a method named evaluation. A caller of the evaluation method can provide a corresponding context (e.g., named EvaluationContext). The EvaluationContext can provide the data that is specific to a particular evaluation of the function. This data can include the values of the variables the function depends on. For instance, for an implicit function the data can include the values of the spatial coordinates X, Y, and Z.

The EvaluationContext can also be used to improve evaluation performance. For example, suppose that one is interested in doing evaluations in only a certain region of space. Suppose further that the expression min (expr1, expr2) is to be evaluated. If it can be known that in this region of space expr1 is always smaller than expr2, then an indication of such can be stored in the EvaluationContext. Subsequently, during evaluation the knowledge that expr1 is always smaller than expr2 can be used to avoid evaluating expr2. It is observed that this optimization has wide applicability. As just some examples, the if, min, max, addition, multiplication, division, subtraction nodes are amenable to this optimization, as are various oracles including the bounding volume hierarchy (BVH) oracle. The optimization can, for instance, be referred to as subtree pruning. As another example, the EvaluationContext can be a useful place to store semantic information. For instance, the EvaluationContext can be used to check whether, for a certain point or region in space, a given function only depends on a certain AstNode (e.g., a lattice or mesh).

The implicit kernel using ASTs can support various types (e.g., scalar and/or vec3). Values of these various types can be stored in several ways. According to a first approach, the values can be stored according to a single object that exposes a single interface. Here, potential differences between the types can be handled in an ad-hoc fashion. In particular, there can be a single object (e.g., named value) that can hold values of any type, including interval types. This design provides high flexibility. For instance, to add a new type one can add members to the Value class and, for edge cases where the new type does not behave in the expected way, potentially add code. It is noted that this first approach, in an aspect, leverages the observation that the desired types can be expected to behave similarly to one another a high percentage of the time (e.g., 95% of the time).

According to a second approach for storing the values of the various types, the desired types can be tied to concrete types/classes of a given programming language (e.g., the desired types can be tied to concrete C++ types/classes). For various embodiments, the noted first approach can be considered preferable over the second approach. Such can transpire where, for instance, it is taken to be the case that an employed tree walking interpreter does not scale well compared to using a dynamic Value type. Such a view can be taken, for example, where it is the case that there would be call to implement the aforementioned evaluation interface for each type for which support is desired.

Turning to types and values for the implicit kernel that uses ASTs, a distinction can be made between an abstract type (i.e., a symbolic representation of a mathematical object) and the representation of that type. The following pseudocode enum lists just some examples of types that can be supported:

```
enum class Type {
  Vec3,
  VecN,
  TriBool,
  Scalar,
  Integer,
  ListVec3,
}
```

To instantiate a given abstract type, the type can be mapped to a concrete type (e.g., to a concrete C++ type). For instance, a class (e.g., named Value) can be introduced. This class can dynamically represent any concrete type for which it is desired to provide support. Even where it is not desired to support dynamic typing, maintaining the information dynamically can yield benefits including convenience, simplified implementation, and flexibility. It is noted that even where such dynamic maintenance introduces increased interpreter overhead, the noted benefits can be expected to outweigh the increased overhead.

As just an illustration, the following pseudocode class Value can support representing in double precision: a) the types Scalar, ListVec3, Vec3, and ListVec3; and b) the interval type:

```
class Value {
public:
template<class... Args>
Value(Args&&... args) : mData{forward<Args>(args)...} { }
  enum TriBool { False, True, FalseOrTrue }
  TriBool asTriBool( ) const;
  Type type( ) const;
  const Variant& get( ) const;
private:
  using Variant = variant<
    TriBool,
    long,
    double, Vec3, Vec<double>, vector<Vec3>,
    Interval, Vec3<Interval>, Vec<Interval>, vector<Vec3<Interval>>
>;
  Variant mData;
}
```

With reference to TriBool above, it is noted this representation of Boolean supports not only true and false states, but also a TrueOrFalse state. The inclusion of the TrueOrFalse state can be useful, for instance, for conditional expressions for Intervals, as they do not necessarily evaluate to either true or false.

Because the above Value type contains types that behave in a similar way, a common interface can be exposed to manipulate Value objects. For example, a min function can be provided as per the following pseudocode:

```
  Value min(Value a, Value b) {
    struct MinImpl {
      // Generic implementation
      template<class T>
      Value operator( )(const T& a, const T& b) { return
      Value{min(a,b)};
}
      // Special case: min(double, Vec3)
      Value operator( )(double a, Vec3 b) { return Vec3{min(a1, b.x),
min(a1, b.y), min(a1, b.z)}; }
      // Catch all
      template<class T1, class T2>
      Value operator(T1, T2) { throw
InvalidTypeException(“Invalid min operation”); }
  };
    return visit(MinImpl{ }, a.get( ), b.get( ));
  }
```

Also, additional concrete type representations can be added. For example, where it is desired to add support for 32-bit float representation, the types float, Vec3f, Vec<float>, vector<Vec3f> can be added to the variant contained in Value. Where, for instance, a newly added type satisfies the syntactic requirements of the generic implementation, the functions that manipulate Value objects need not be altered. Further, a dynamic matrix type (named Matrix for the at-hand example) can be used to add array evaluation of size Size by adding the types Vector<Size>, Matrix<Size, 3>, MatrixX<Size, Dynamic>, vector<Matrix<Size, 3>> to the variant contained in Value. Also, support can be added for further representations (e.g., for an arbitrary precision type, such as the arbitrary precision type in the GNU multiple precision arithmetic Library (GMP)).

Considering AstNode representations/operations with respect to the implicit kernel using ASTs, it is noted that according to various embodiments a diverse set of operations can be accommodated by using a class hierarchy to represent different operations. By way of this approach, it is not only possible to store common data in a base class, but also possible to store heavier weight data structures in specific nodes where appropriate. As just an illustration, there can be call that a variadic min/max node store a std::vector of input arguments. Here it can be inefficient to have that member in every node, despite it being called for only in a single node. The following pseudocode provides an example AstNode struct:

```
  struct AstNode {
    virtual Value evaluate(const EvaluationContext& context) const = 0;
    virtual AstNode* derivative(AstNode* dependantVariable, const
FreeVariable& freeVar) const =
  0;
    virtual size_t numInputs( ) const = 0;
    virtual AstNode* input(size_t i) const = 0;
    // This function can be used to lower the AST to an instruction
stream.
    // We skip the details in this document.
    virtual Register emitBytecode(Generator& generator) const = 0;
  Type type;
    // Metadata
    optional<double> lipschitz;
    optional<BoundingBox> boundingBox;
    bool isSdf = false;
  };
```

In an aspect, the above evaluate method recursively calls the evaluate method of its ancestors. For example, a hypothetical Add node can store two AstNode objects for the two summands. A call to the evaluate method of Add can then recursively call the evaluate method for returned summands (e.g., for each returned summand), and then return the sum of the two values. Such a way of evaluating an expression can be referred to as an AST walking interpreter.

To evaluate a specific AstNode, specific values can be assigned to the Free Variable nodes via the EvaluationContext, and the evaluate method can be called. In contrast, according to conventional approaches, expression evaluation is more complicated, typically working in three steps. According to a first such step all nodes are sorted in topological order and then stored in a linear buffer. According to a second such step, in order to store temporary variables, memory is associated with each node. Then, according to a third such step the linear buffer is walked through, and the operation associated with each node is run. As such, conventional approaches are not only more complicated than the tree walking interpreter discussed herein, but also do not readily generalize to, for instance nontrivial control flow statements. Further still, using these conventional approaches it is difficult to implement various optimizations, including high level algorithmic optimizations. It is noted that array evaluation can be used to increase performance when using the tree walking interpreter. Further, the interface can expose a generateBytecode function that can be used to turn a syntax tree into a lower-level representation that is well suited for fast evaluation.

According to an example implementation, there can be three types of metadata attached to a node: a) an optional Boolean indicating whether the node represents a signed distance field; b) an optional bounding box; and c) a Lipschitz constant. The first two metadata types can be optional because the nodes can represent expressions that do not represent solid bodies (e.g., where a Type::Scalar is not output, a solid body is not expected to be represented).

Considering free variables versus constants where the implicit kernel using ASTs is employed, according to various embodiments a special Free Variable node can be implemented. This FreeVariable node can represent a given variable for which it is desired to evaluate the expression tree. As just an illustration, the spatial coordinates (X, Y, Z) can be a specific Free Variable object. According to the following pseudocode example, this global object is named Euclidean Variable:

```
  struct FreeVariable : AstNode {
    Value evaluate(EvaluationContext& context) const override {
      return Value{context.freeVariableValues[id]};
    }
    int id;
  }
  constexpr static FreeVariable EuclideanVariable{.type = Type::Vec3, .id
= 0};
```

Constant values can be generated using a constant node:

```
struct Constant : AstNode {
  Value evaluate(EvaluationContext&) const override { return value; }
  Value value;
}
```

The Constant node can be amenable to various optimizations. For example, the Constant node can be folded with other Constant nodes.

Considering Variadic Min where the implicit kernel using ASTs is employed, implementing an evaluation method for the VariadicMin operation can involve running over all of the inputs, recursively evaluating them, and reducing the result into a single value using a min function that is implemented on the generic Value type. An illustration of such is shown via the following pseudocode:

```
struct VariadicMin : AstNode {
  Value evaluate(EvaluationContext&) const override {
    Value result{Inf};
    for(AstNode* input : inputs) {
      result = min(result, input−>execute( ));
    }
    return union;
  }
  vector<AstNode*> inputs;
}
```

Although the VariadicMin operation is discussed here, similar functionality can be implemented with respect to other variadic operations (e.g., variadic max and smooth unions).

Various CISC operations and/or primitives can be implemented where the implicit kernel using ASTs is employed. As just some examples, implemented CISC operations can include Dot, Length, and reflect, and implemented CISC primitives can include Sphere, and Torus. Also where the implicit kernel using ASTs is employed, a ConditionalNode can be used to allow for conditional evaluation of an expression. The ConditionalNode can provide for nonlinear control flow, and for Interval representations where a condition can be true and false at the same time. An example implementation of ConditionalNode is shown via the following pseudocode:

```
struct ConditionalNode: AstNode {
  Value evaluate(EvaluationContext& context) const override {
    auto cond = condition−>evaluate(context).asTriBool( );
    if(cond == TriBool::True) {
      return consequent−>evaluate(context);
    }
    else if(cond == TriBool::False) {
      return alternate−>evaluate(context);
}
else {
      // Can only happen for interval representations
      auto i1 = consequent−>evaluate(context);
      auto i2 = alternate−>evaluate(context);
      return joinIntervals(i1, i2);
} }
  AstNode* condition;
  AstNode* consequent;
  AstNode* alternate;
}
```

Turning to subtree pruning where the implicit kernel using ASTs is employed, subtree pruning can, for instance, be enabled using the recursive, AST walking evaluation. In particular, a Cache object can be introduced. The Cache object can cache data in order to support taking computational short cuts for various computations. As just an illustration, where it is determined that for certain considered inputs the expression min(a,b) is always equivalent to a (i.e., a<b for all considered inputs), then such information can be cached. As another illustration, for a VariadicMin operation a Boolean value can be stored for each input indicating whether that input contributes to min operation.

Nodes that can benefit from caching data in order to take computational short cuts as discussed include: a) Min and Max; b) VariadicMin and VariadicMax; c) Add, Sub, Mul, and Div; d) Conditionals and other nodes that result in Booleans.; and e) BvhNode.

Turning to Min and Max, caching can occur where one input does not contribute. Turning to VariadicMin and VariadicMax, the input that contributes to the final min or max can be cached. As to Add, Sub, Mul, and Div, where they are constant, the values of input arguments can be cached. Also, where it is constant the value of the whole expression can be cached. Such functionality for Add, Sub, Mul, and Div can provide benefits including accelerating smooth unions. Considering conditionals and other nodes that result in Booleans, the value of the Boolean can be cached. As to BvhNode, a BvhNode can be cached.

An example implementation of the Cache object is shown via the following pseudocode:

```
  struct Cache {
    // For the VariadinMin operation.
    Cache(vector<bool> isDead);
    // For conditionals.
    Cache(Bool bool);
    // For arithmetic expressions
    Cache(Value value, int subtree);
    // In case the entire result is constant in an arithmetic expression.
    Cache(Value value);
    // In order to cache the index of a bvh node in the BvhNode (see
below).
    Cache(int bvhNodeIdx);
    bool hasValue( ) const;
    bool isDead(int i) const;
    bool isConstant(int i, Value&) const;
    bool isConstant(Value&) const;
    int bvhNodeIdx( );
    ..
  }
```

According to various embodiments, an array of caches can be stored in the EvaluationContext. As just an illustration, suppose that one is interested in evaluating the expression for a given bounding box. Here, the expression can be evaluated using interval values that are initialized to the bounding box. While running the interval evaluation, the temporary interval values can be used to populate the caches where possible.

As to VariadicMin, an example implementation of how, for instance, the VariadicMin node can cache data during the interval evaluation is shown via the following pseudocode:

```
  Value VariadicMin::evaluate(EvaluationContext& context) const override
{
    if(context.pruneSubtrees( )) {
      // If the pruneSubtrees( ) function is true, then we know we're in
interval evaluation mode.
      // Recursively evaluate all intervals
      vector<Value> intervals = ...
      // Find index of interval with the smallest lower interval bound.
      int minIdx = ..
      // Set to true for intervals whose left bound is to the right of the
      // right bound of intervals[0]
      vector<bool> isDead = .. ;
      context.caches[id] = Cache(isDead);
      ..
  } }
```

Then, the following pseudocode shows an example of how the cache can be populated for an Add node:

```
Value Add::evaluate(EvaluationContext& context) const override {
  auto& cache = context.caches[id]
  if(context.pruneSubtrees( )) {
    Value v1 = input1−>evaluate(context);
    Value v2 = input2−>evaluate(context);
    if(v1.isConstant( ) && v2.isConstant( )) {
      cache = Cache(v1.lower( ) + v2.lower( ));
    }
    else if(v1.isConstant( )) {
      cache = Cache(v1, 0);
    }
    else if(v2.isConstant( ))) {
      cache = Cache(v2, 1);
}
    return v1 + v2;
  }
.. }
```

Subtree pruning can include first running an interval evaluation for a bounding box of interest, and then populating the caches. Subsequently, the expression can be evaluated for points that are within the bounding box. This approach can yield faster results than existing approaches. For instance, the cached data can be used to skip evaluation of various nodes. The following pseudocode provides an example of how the caches can be used to accelerate evaluation of the VariadicMin node:

```
  Value VariadicMin::evaluate(EvaluationContext& context) const override
{
    ..
    Value result{Inf};
    for(auto* input : inputs) {
      if(cache.hasValue( ) && cache.isDead(i)) {
        continue;
  }
      result = min(result, input−>execute( ));
    }
    return result;
  }
```

Next, the following pseudocode shows an example of how the Add node can be accelerated using the cached data from a previous interval evaluation:

```
Value Add::evaluate(EvaluationContext& context) const override {
  ..
  Value result;
  if(cache.isConstant(result)) {
    return result;
  }
  else if(cache.isConstant(0, result)) {
    return result + input1−>evaluate(context);
  }
  else if(cache.isConstant(0, result)) {
    return input0−>evaluate(context) + result;
  }
  return input0−>evaluate(context) + input1−>evaluate(context);
}
```

Turning to transformations and remapping where the implicit kernel using ASTs is employed, a RigidTransformation node can be introduced. The RigidTransformation node can represent a rigid transformation using an angle-axis representation for the rotation and a vector for the translation part. Such is shown via the following example pseudocode:

```
  struct RigidTransformation : AstNode {
    Value evaluate(EvaluationContext& context) {
      auto axis = axisNode−>evaluate(context);
        Value angle = angleNode−>evaluate(context);
        Value translation = translationNode−>evaluate(context);
        Value v = input−>evaluate(context);
        return v * cos(angle) + cross(axis, v)*sin(angle) + k * dot(k,
v) * (1. − cos(angle));
  }
    AstNode* axisNode;
    AstNode* angleNode;
    AstNode* translationNode;
    AstNode* inputNode;
  }
```

More generally, according to the functionality discussed herein it is possible to perform a remapping of a function f(x_1, . . . , x_n) for some input x_i and some function g. That is to replace f(x_1, . . . , x_n) with f(x_1, . . . , g(x_i), . . . , x_n). Such is shown via the following example pseudocode:

```
  void remap(AstNode* f, AstNode const* x, AstNode const* g) {
    // Traverse the ancestors of f and gather all nodes which directly
depend on x.
    vector<AstNode*> queue{f};
    vector<pair<AstNode*, int>> directAncestors;
    while(!queue.empty( )) {
      AstNode* node = queue.front( );
      queue.pop_front( );
      for(size_t i = 0; i < node−>numInputs( ); ++i) {
        AstNode* child = node−>input(i);
          if(child == x) {
            directAncestors.emplace_back(node, i);
          }
          else {
            queue.push(child);
  } }
    }
    for(auto [node, idx] : directAncestors) {
      node−>setInput(idx, &g);
    }
  }
```

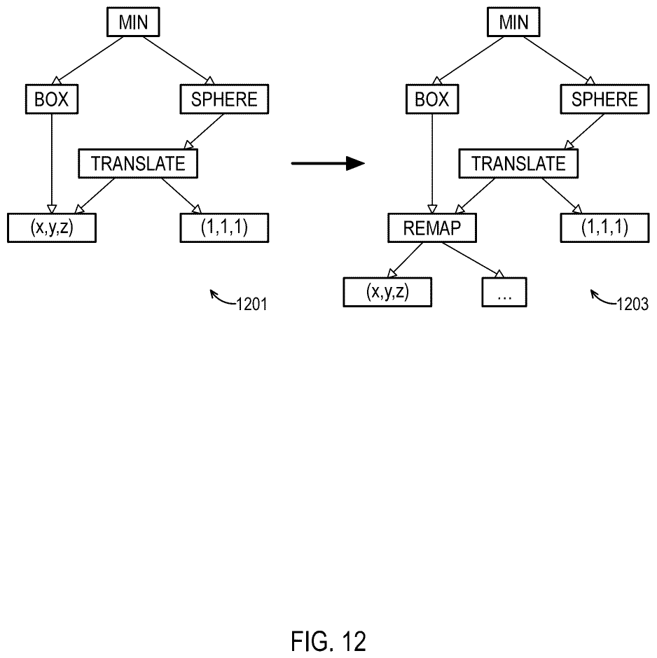

Turning to FIG. 12, shown is an example of the functionality just discussed of transforming an AST from state 1201 to state 1203.

Further, in various embodiments a transform function can be provided. This transform function can, according to the following example pseudocode implementation, take an implicit f and apply a RigidTransformation thereto:

AstNode* transform(AstNode* f, const RigidTransformation& tf) {
remap(f, &EuclideanVariable, &tf);
}

Such functionality can, for instance, allow for a convenience tool (e.g., via a Gizmo) to be provided for implicit objects. As just an illustration, according to the convenience tool where a user clicks on an object, a transform node and three free variables can be generated. The three free variables can serve as inputs for the rotation axis, inputs for the rotation angle, and inputs for the translation, the three free variables being associated with their corresponding convenience tool (e.g., Gizmo) UI elements. In various embodiments implementation can include shader recompilation.

Considering AD where the implicit kernel using ASTs is employed, according to various embodiments a new AST can be generated when performing AD. Such an implementation can yield benefits including being able to compose the derivative operator with various (e.g., all) the evaluation features of the interpreter. In contrast, existing approaches typically implement special gradient and array gradient evaluators that, because they are merely special evaluators, cannot be used with interval evaluation, or other more advanced evaluations (e.g., affine arithmetic). Example AD functionality where the implicit kernel using ASTs is employed is shown via the following example pseudocode:

```
  AstNode* Mul::derivative(AstNode* dependantVariable, const
FreeVariable& freeVar) const {
    if(this == dependantVariable) {
      return &freeVar;
    }
    AstNode* left = new Mul(input1−>derivative, input2);
    AstNode* right = new Mul(input1, input2−>derivative);
    return new Add(left, right);
  }
```

As to oracle integration where the implicit kernel using ASTs is employed, in various embodiments, implementation can leverage existing oracles (e.g., oracles written in view of an existing kernel). According to one approach, the AstNode interface can be implemented for such existing oracles. Here, for instance, a generic wrapper node OracleNode that works for such oracles can be implemented. Further, in various embodiments specialized nodes (e.g., for the GenericBVHOracle or the VolumeMeshFieldOracle) can be added. The following pseudocode shows an example implementation of the noted generic wrapper node OracleNode:

```
  struct OracleNode : AstNode {
    Value evaluate(EvaluationContext& context) const override {
      Value v = input−>evaluate( );
        if(isGradient) {
          return Value{evaluator.derivative(v.asVec3F64( ))};
  }
        if(v.isInterval( )) {
          // get lower and upper bounds from the wrapped Vec3Interval
          Vec3 lower, upper = ..
          return Value{evaluator.interval(lower, upper)};
  }
        return Value{evaluator.value(v.asVec3F64( ))};
    }
    AstNode* derivative(AstNode* dependantVariable, const FreeVariable&
freeVar) const override
  {
      if(isGradient || dependantVariable != &EuclideanVariable) {
          // Fallback to finite differencing
          ..
  }
        return new OracleNode{true, evaluator, input};
    }
    bool isGradient = false;
    ntimp::Evaluator evaluator;
    AstNode* input;
  }
```

Further as to oracle integration where the implicit kernel using ASTs is employed, the VolumeMeshFieldOracle can be improved by using, for instance, the AstNode interface discussed herein. The VolumeMeshFieldOracle can be used for purposes including interpolating multidimensional data.

Were an implementation to provide an oracle interface that only supported scalar types, there would typically be call to perform as many BVH traversals as there were dimensions in the data being interpolated. As an illustration, using such an implementation in a lattice pipeline to interpolate UVW coordinates, there would typically be call for three BVH traversals per query. In contrast, using the approaches discussed herein, a single traversal can be performed, and a Value object of type Type::Vec3 can be returned. Another benefit of using the functionality discussed herein is the ability to return a dynamically sized array of values. The ability to return a dynamically sized array of values can be useful, for instance, for periodic cell maps, as periodic cell maps do not necessarily have unique inverses.

Additionally as to oracle integration where the implicit kernel using ASTs is employed, the subtree pruning optimization can be integrated with the GenericBVH oracle. As just an illustration, given a Vec3<Interval> representation, the BVH can be traversed, and BVH nodes can be pruned where they are too far away in order to contribute to the result. The following pseudocode shows an example implementation of such functionality:

```
  struct GenericBvhNode : AstNode {
    Value evaluate(EvaluationContext& context) const override {
      Value v = input−>evaluate(context);
        auto& cache = context.caches[id];
      if(v.isInterval( )) {
          // turn interval into bounding box
          BoundingBox bb = ..;
          auto result = bvh−>getDistanccBound(bb);
          cache = result.nodeIdx;
          return Value{result.distance};
  }
        int nodeIdx = cache.hasValue( ) ? cache.bvhNodeIdx( ) :
GenericBVH::InvalidNodeIdx;
        double sdf = bvh−>getSignedDistance(v.asVec3F64( ), nodeIdx);
    }
    AstNode* input;
    GenericBVH* bvh;
    int id;
  }
```

Were an implementation to handle derivatives such that it were only possible to calculate gradient with respect to spatial x, y, and z coordinates, then it would not be possible, for instance, to compute higher derivatives, or derivatives with respect to other free variables. In contrast, using the approaches discussed herein the GenericBvh node can compute derivatives by storing metadata so as to be able to, for instance, not only return the signed distance, but also higher derivatives to an at-hand mesh or lattice. It is noted that, in various embodiments, if a triangle mesh originates from a CAD body, the associated parasolid object can be stored in the node object, such as to facilitate computing correct gradients.

Also with regard to the implicit kernel using ASTs, a tree walking interpreter implementation, a bytecode interpreter implementation, and a JIT compilation implementation will now be discussed. Although discussion of the implicit kernel using ASTs so far generally regarded the use of a tree walking interpreter, other possibilities exist including the use of a bytecode interpreter and the use of JIT compilation to native code.

A bytecode interpreter, in an aspect, utilizes a linear stream of instructions. Where each instruction has the same size, pointer indirection can be avoided. It can be beneficial that a bytecode interpreter only support simple types (e.g., scalars), and that more complex types (e.g., Vec3 and ListVec3) be lowered (e.g., to scalar). It can also be beneficial that high level control flow (e.g., conditionals) be lowered (e.g., into jump instructions). It is noted that where a type is lowered to scalar, according to various embodiments there is no call to specify a corresponding concrete type to be used when evaluating.

A JIT compiler can turn a bytecode representation into native instructions. Said somewhat differently, a JIT compiler can perform instruction encoding. In various embodiments, JIT efficiency can be increased by mapping temporary values to registers (e.g., to specific registers) of the target. It is noted that such mapping can be referred to as register allocation. Also, it is noted that, in various embodiments, a JIT compiler can, in contrast to a bytecode interpreter, emit code that handles a single value type, (e.g., single or double precision, or interval arithmetic).

Considering overhead for the bytecode interpreter, the time that it takes to run the bytecode interpreter for a given input can be calculated as the sum:

$$T = T\_native + T\_extra + T\_interpreter .$$

Here, T_native is the time it takes to do the actual computation. As just an illustration, if evaluating a square root T_native can represent the time it takes to run the sqrt instruction. T_interpreter can represent the overhead induced by the interpreter (e.g., overhead induced by branching and/or function calls). T_extra can represent the time it takes the native code to set up the actual computation (e.g., fetching data from registers (and/or from memory), loop overhead, and/or writing data to registers (and/or to memory)). It is noted that an array evaluator for n inputs can take a time T=n*(T_native+T_extra)+T_interpreter to run. As such, by choosing a large enough value for n, T_interpreter/T can be brought below a desired threshold.

Various aspects of using a tree walking interpreter, using a bytecode interpreter, and using JIT compilation will now be compared for the circumstance where the implicit kernel using ASTs is employed.

Considering batched evaluation where the implicit kernel using ASTs is employed, such is typically fast when using the tree walking interpreter, fast when using the bytecode interpreter, and very fast when using JIT compilation. The expected fast speed when using the tree walking interpreter can be because interpreter overhead can be amortized (e.g., where there is a sufficient quantity of points). The expected fast speed when using the bytecode interpreter can be because interpreter overhead can be amortized. It is noted that batched evaluation using JIT compilation can be very fast especially for pure implicits. JIT compilation can achieve high speeds, for instance, where temporaries can be kept in registers. As such, batched evaluation can be faster than array evaluation.

As to single point evaluation where the implicit kernel using ASTs is employed, such can be slow when using the tree walking interpreter. This slowness can be due to interpreter overhead, but can be negligible for expressions that contain oracles. Then, single point evaluation can be fast when using the bytecode interpreter due to low interpreter overhead. Single point evaluation can be very fast when using JIT compilation (e.g., for pure implicits). Further, variadic union can use BVH pruning where every input is an SDF.

In various embodiments, tree optimizations can be implemented where the implicit kernel using ASTs is employed. For example, a CSE pass can be performed. Here, benefits including preventing trees from becoming overly large can accrue. As another example, by performing derivative expression computation large portions of a tree can potentially become identically zero (e.g., because the portions do not depend on the variable with respect to which the derivative is being taken). As such, in various embodiments constant folding can be implemented, and/or specialized code that handles derivative expression computation directly when calling the derivative method can be provided.

Also, capabilities of the implicit kernel using ASTs can include support for various forms of interactivity. For instance, a UI can be provided that allows a user to provide vars that can be passed to one or more shaders (or other entities). As just an illustration, provided interactivity can allow for control of a GLSL shader (e.g., a GLSL particle emitter shader).

It is noted that a model generated via one or more of the implicit kernels discussed herein (e.g., the implicit kernel using ASGs and/or the implicit kernel using ASTs), unlike a model generated using a traditional CAD modeling kernel, can be considered to be program (e.g., a program in the form of an ASG) that describes, for instance, the relationships between various elements of a design. The model itself can be thought of as containing various possible designs (e.g., all possible designs), and evaluations of the designs can be executed in parallel to better understand different aspects of the designs. Having a programmatic representation of a design can yield benefits including enabling fast shape derivatives, enabling optimization, and enabling integration of geometry into various pipelines (e.g., AI/ML pipelines). It is also noted that among benefits yielded through use of the kernels discussed herein can be leveraging GPU and/or parallel computation capabilities of employed computer systems.

### Hardware and Software

According to various embodiments, various functionality discussed herein can be performed by and/or with the help of one or more computers. Such a computer can be and/or incorporate, as just some examples, a personal computer, a server, a smartphone, a system-on-a-chip, and/or a microcontroller. Such a computer can, in various embodiments, run Linux, MacOS, Windows, or another operating system.

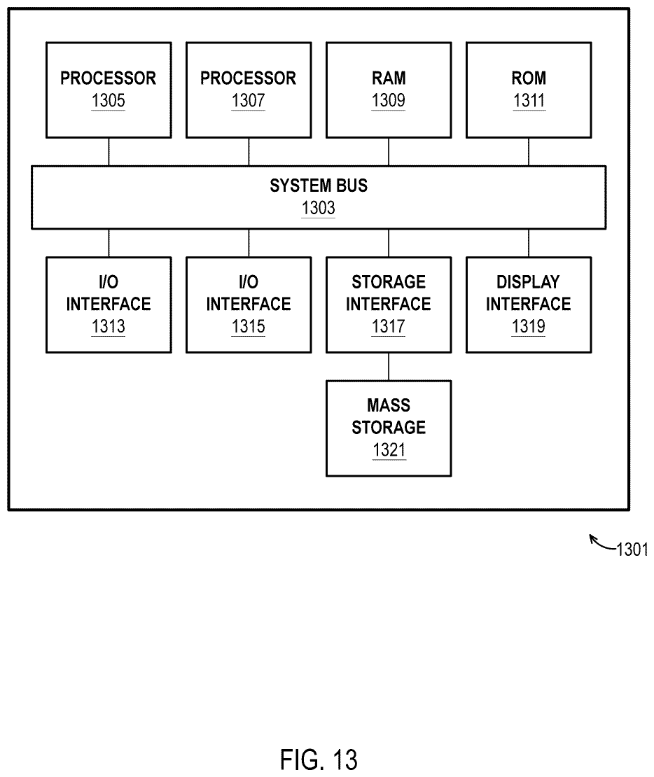

Such a computer can also be and/or incorporate one or more processors operatively connected to one or more memory or storage units, wherein the memory or storage may contain data, algorithms, and/or program code, and the processor or processors may execute the program code and/or manipulate the program code, data, and/or algorithms. Shown in FIG. 13 is an example computer employable in various embodiments of the present invention. Exemplary computer 1301 includes system bus 1303 that operatively connects two processors 1305 and 1307, random access memory (RAM) 1309, read-only memory (ROM) 1311, input output (I/O) interfaces 1313 and 1315, storage interface 1317, and display interface 1319. Storage interface 1317 in turn connects to mass storage 1321. Each of I/O interfaces 1313 and 1315 can, as just some examples, be a Universal Serial Bus (USB), a Thunderbolt, an Ethernet, a Bluetooth, a Long-Term Evolution (LTE), a 5G, an IEEE 488, and/or other interface. Mass storage 1321 can be a flash drive, a hard drive, an optical drive, or a memory chip, as just some possibilities. Processors 1305 and 1307 can each be, as just some examples, a commonly known processor such as an ARM-based or x86-based processor. Computer 1301 can, in various embodiments, include or be connected to a touch screen, a mouse, and/or a keyboard. Computer 1301 can additionally include or be attached to card readers, DVD drives, floppy disk drives, hard drives, memory cards, ROM, and/or the like whereby media containing program code (e.g., for performing various operations and/or the like described herein) may be inserted for the purpose of loading the code onto the computer.

In accordance with various embodiments of the present invention, a computer may run one or more software modules designed to perform one or more of the above-described operations. Such modules can, for example, be programmed using Python, Java, JavaScript, Swift, C, C++, C #, and/or another language. Corresponding program code can be placed on media such as, for example, DVD, CD-ROM, memory card, and/or floppy disk. It is noted that any indicated division of operations among particular software modules is for purposes of illustration, and that alternate divisions of operation may be employed. Accordingly, any operations indicated as being performed by one software module can instead be performed by a plurality of software modules. Similarly, any operations indicated as being performed by a plurality of modules can instead be performed by a single module. It is noted that operations indicated as being performed by a particular computer can instead be performed by a plurality of computers. It is further noted that, in various embodiments, peer-to-peer and/or grid computing techniques may be employed. It is additionally noted that, in various embodiments, remote communication among software modules may occur. Such remote communication can, for example, involve JavaScript Object Notation-Remote Procedure Call (JSON-RPC), Simple Object Access Protocol (SOAP), Java Messaging Service (JMS), Remote Method Invocation (RMI), Remote Procedure Call (RPC), sockets, and/or pipes.

Moreover, in various embodiments the functionality discussed herein can be implemented using special-purpose circuitry, such as via one or more integrated circuits, Application Specific Integrated Circuits (ASICs), or Field Programmable Gate Arrays (FPGAs). A Hardware Description Language (HDL) can, in various embodiments, be employed in instantiating the functionality discussed herein. Such an HDL can, as just some examples, be Verilog or Very High-Speed Integrated Circuit Hardware Description Language (VHDL). More generally, various embodiments can be implemented using hardwired circuitry without or without software instructions. As such, the functionality discussed herein is limited neither to any specific combination of hardware circuitry and software, nor to any particular source for the instructions executed by the data processing system.

### Exemplary Methods of Computer-Aided Design

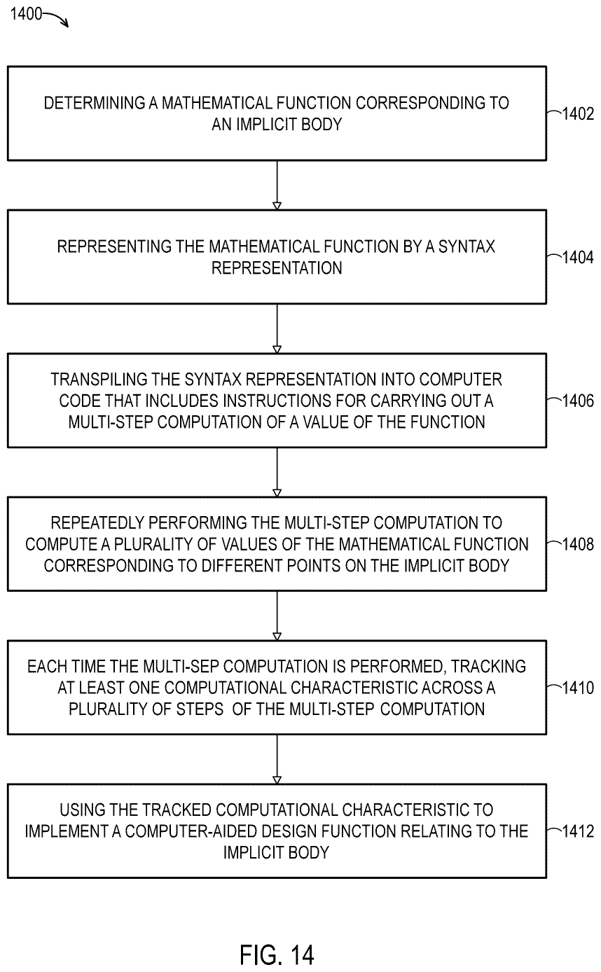

This section describes further exemplary method of computer-aided design, according to aspects of the present teachings; see FIGS. 14-17.

FIG. 14 is a flowchart depicting a method 1400 of computer-aided design that utilizes a form of tracking to implement a computer-aided design function in the context of implicit CAD modeling. At step 1402, a mathematical function corresponding to an implicit body is determined. For example, as described previously, one or mathematical functions such as signed distance functions may be composed to represent scalar fields, where the implicit body corresponds to zero isosurfaces of the scalar fields represented by the mathematical function(s). In this manner, a mathematical function may correspond to the surface of a sphere, a cylinder, a cube, and/or the like.

At step 1404, the mathematical function is represented by a syntax representation, such as a graph (e.g., as abstract semantic graphs (ASGs)) and/or as trees (e.g., as abstract syntax trees (ASTs)). As has been previously described, by evaluating a syntax representation, such as an abstract semantic graph representing a mathematical function, the scalar field value at any point can be computed. In some cases, a syntax representation may be evaluated directly to determine scalar field values.

In other cases, as indicated at step 1406, a syntax representation of a mathematical function may be transpiled (i.e., transformed) into computer code for carrying out a multi-step computation of a value of the mathematical function at each particular point of interest. For example, the multi-step computation may include hundreds of steps, thousands of steps, or even greater numbers of steps, each of which will be performed to determine the value of the mathematical function at any particular point in a desired coordinate space.

To determine the values of the mathematical function at all of the points of interest, corresponding to points on the implicit body, the multi-step computation of step 1406 must be performed across an array of points. Accordingly, at step 1408, the multi-step computation is repeatedly performed to compute a plurality of values of the mathematical function corresponding to different points on the implicit body. The number of repetitions of the computation may be determined, for example, by the size of the implicit body, the size of a bounding box within which the implicit body is disposed, and/or a desired spatial density of points where the value of the function is to be computed.

At step 1410, each time the multi-step computation is performed to compute a value of the mathematical function, at least one computational characteristic is tracked across a plurality of steps of the multi-step computation. For example, tracking identity operations, such as multiplying by one or adding zero to a previous calculation step, can be used to identify steps within the multi-step calculation that do not contribute anything to the final value of the function at particular points. This information can then be used to eliminate steps of the computation when calculating the field value for surrounding points, leading to potentially massive gains in computational efficiency.

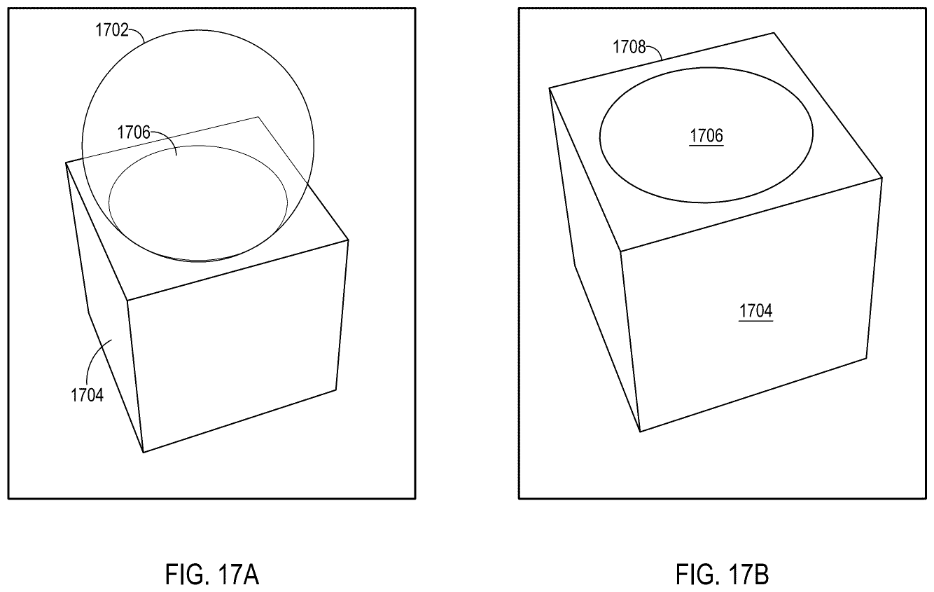

As another example, tracking partial derivatives across calculation steps can be used to orient surfaces. For example, FIGS. 17A-17B depict a sphere 1702 being subtracted from a box (or cube) 1704 to create an indentation 1706. In the CAD output of FIG. 17B, indentation 1706 has a black border 1708, indicating that indentation 1706 is detected as a separate region from the rest of box 1704. Though indentation region 1706 is fully influenced by sphere 1702 (the shape of the indentation is spherical) the orientation of the surface of indentation 1706 is the opposite of that of sphere 1702 used to create the indentation. The orientations are opposite because the operation at play in this example is a subtraction. Because the sphere was subtracted from the box, the partial derivative of the resulting indentation with respect to the sphere is −1, meaning that gradients and surface normal vectors of sphere 1702 and indentation 1706 point in opposite directions. Tracking partial derivatives provides an elegant mechanism to consistently orient the surfaces in examples such as this one, in which shapes are added or subtracted.

As still another example, selected values of the mathematical function, corresponding to particular regions of an implicit body, can be labeled with a tag that is propagated through the steps of the multi-step calculation, and these tags may be used for various purposes. According to aspects of the present teachings, such propagated labels or tags also represent computational characteristics that may be tracked in step 1410 of method 1400.

At step 1412, the tracked computational characteristic is used to implement a computer-aided design function relating to the implicit body. For instance, tracked identity operations can be used to distinguish regions of the implicit body that have been modified, relative to some initial geometry, from regions of the implicit body that have not been modified. In cases where multiple geometric shapes are combined into a complex geometry, this may allow parts of the complex geometry to be represented by portions of the original geometric shapes, while other parts of the geometry are represented by a merged superposition of the original shapes. In some cases, the various unmodified and modified portions of the complex geometry may be color coded or otherwise distinguishable from each other, as depicted, for example, in FIG. 7.

Still with reference to step 1412, the tracked computational characteristic may be used, for example, to label one or more regions of the implicit body based on a selected property of each region. As discussed above, this selected property may be whether or not the region has been modified from its original geometric representation. Alternatively or in addition, regions may be labeled based on other selected properties, such as a desired density or fidelity of points to be calculated in a region, a boundary condition to be applied to a region, or simply to identify a region in a manner that can be propagated to downstream software applications. In some cases, distinct faces of an implicit body may be separately labeled, in which case the presence of a pair of labels can be used to identify an edge where the corresponding faces meet. Similarly, vertices or corners can be identified by the combination of labels of the implicit body faces meeting at particular points.

Yet further with reference to step 1412, when the tracked computational characteristic includes an identity operation, the computer-aided design function may be associating a point on the implicit body with its step of creation in a multi-step computer-aided design workflow. In other words, tracking identity operations allows a determination of when a particular point on the implicit body first appeared during a user-guided CAD design process. This may, for example, allow the user to navigate to a corresponding step in a CAD workflow (or “notebook”), simply by clicking on or otherwise selecting a point on the implicit body, at which point the step of creating that point in the workflow will be identified. This may be helpful for efficient troubleshooting and/or modification of selected parts or regions of an implicit body geometry.

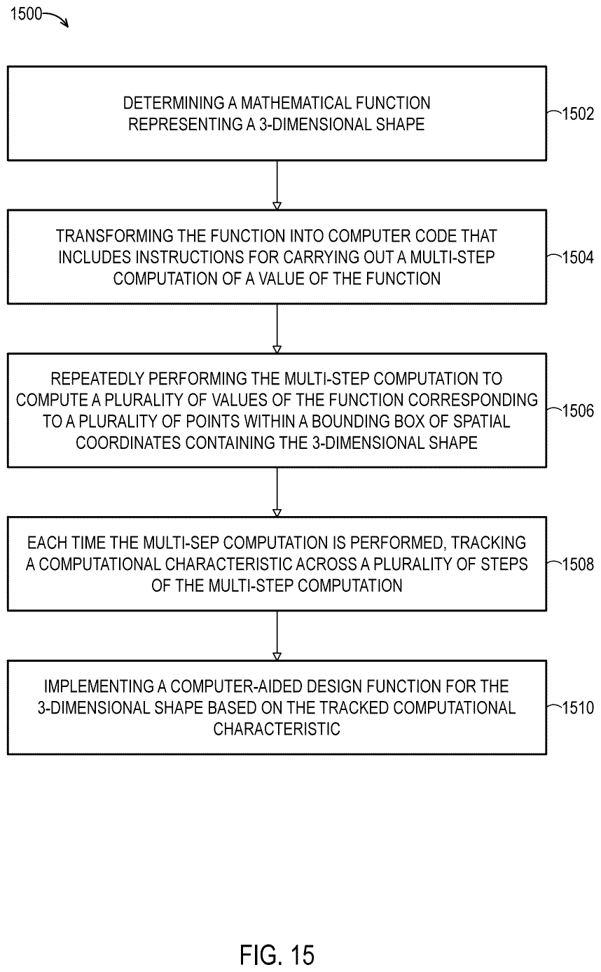

FIG. 15 is a flowchart depicting another method 1500 of computer-aided design that utilizes a form of tracking to implement a computer-aided design function in the context of implicit CAD modeling. At step 1502, a mathematical function representing a 3-dimensional shape is determined. For example, as described previously, one or mathematical functions such as signed distance functions may be composed to represent scalar fields, and the 3-dimensional shape may correspond to zero isosurfaces of the scalar fields represented by the mathematical function(s). In this manner, a mathematical function may correspond to the surface of any 3-dimensional shape such as a sphere, a cylinder, a cube, and/or the like. Combinations of functions (which may be combined into a single complex function) may likewise correspond to more complex 3-dimensional shapes, such as the merger of two or more simpler geometric shapes.

At step 1504, the mathematical function of step 1502 is transformed into computer code that includes instructions for carrying out a multi-step computation of a value of the mathematical function at each particular point of interest. The computer code may be, for example, bytecode that may be evaluated by a CPU, OpenGL shading language (GLSL) code that may be evaluated by a GPU, resulting in potential efficiency gains due to parallelism, or machine code with potential benefits including faster CPU execution, more efficient memory access, and/or more efficient memory usage. For example, the multi-step computation may include hundreds of steps, thousands of steps, or potentially even millions of steps, each of which will be performed to determine the value of the mathematical function at any particular point in a desired coordinate space.

At step 1506, the multi-step computation is repeatedly performed to compute a plurality of values of the mathematical function corresponding to a plurality of points that define the 3-dimensional shape. For example, the computation may be performed across points within a bounding box of spatial coordinates containing the 3-dimensional shape. A suitable bounding box may be determined automatically by a processor, or it may be specified by a user based on known dimensions of the 3-dimensional shape. Accordingly, the number of repetitions of the multi-step computation may be determined by the size of the 3-dimensional shape, the size of the bounding box containing the 3-dimensional shape, and/or a desired spatial density of points where the value of the function is to be computed to represent the 3-dimensional shape.

At step 1508, each time the multi-step computation is performed to compute a value of the mathematical function, a computational characteristic is tracked across a plurality of steps of the multi-step computation. Tracking an identity operation, such as multiplying by one or adding zero to a previous calculation step, can be used to identify steps within the multi-step calculation that do not contribute anything to the final value of the function at particular points, or that do not change the value of the function across subsets of steps. This information can then be used to eliminate steps of the computation that do not need to be performed, leading to potentially massive gains in computational efficiency. Tracking partial derivatives across calculation steps can be used to orient surfaces correctly when a 3-dimensional shape is formed by the addition or subtraction of two or more other shapes, as described previously. Labeling and tracking selected values of the mathematical function corresponding to particular regions of the 3-dimensional shape can also be used for various purposes, as described below with respect to step 1510.

At step 1510, a computer-aided design function for the 3-dimensional shape is implemented based on the tracked computational characteristic. For instance, identity operations tracked across multiple computation steps can be used to identify regions of the 3-dimensional shape that have not been modified relative to some prior shape. In cases where multiple 3-dimensional shapes are combined into a more complex shape, such tracking of an identity operation may allow parts of the complex geometry to be represented by portions of the original geometric shapes, while other parts of the geometry are represented by a merged superposition of the original shapes or by some other complex shape. In some cases, the various unmodified and modified portions of the complex geometry may be color coded or otherwise distinguishable from each other.

A tracked computational characteristic also may be used to label regions of the 3-dimensional shape based on a selected property of each region. This property may be whether or not the region has been modified from its original geometric representation, a desired density or fidelity of points to be calculated in a region, a boundary condition to be applied to a region, or a tag that identifies a region in a manner that can be propagated to third-party software applications. Different surfaces of a 3-dimensional shape may be separately labeled, in which case the presence of a pair of labels can be used to identify an edge where the corresponding faces meet, and the presence of other combinations of labels can be used to identify particular points as corners or vertices of the 3-dimensional shape.

When the tracked computational characteristic includes an identity operation, the implemented computer-aided design function may be associating a point on the 3-dimensional shape with its instant of creation in a computer-aided design workflow, allowing a user to determine conveniently when a particular point on the 3-dimensional shape first appeared during a CAD design process. This may, for example, allow the user to navigate to a corresponding step in a multi-step CAD workflow by selecting a point on the 3-dimensional shape, at which point the step of creating that point in the workflow will be identified based on analysis of the tracked identity operation(s). This may allow efficient troubleshooting or modification of specific points or regions of a 3-dimensional shape being modeled or designed.

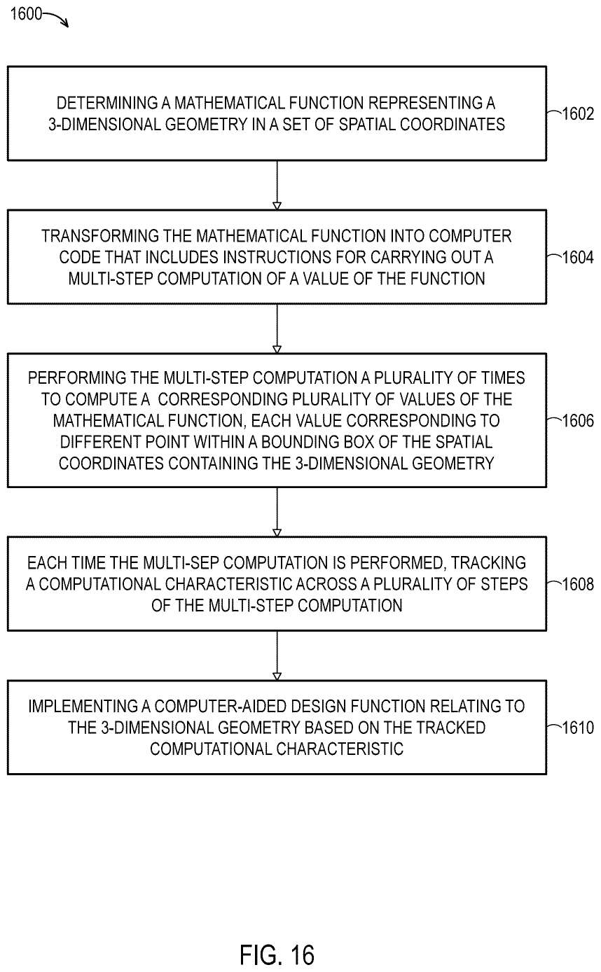

FIG. 16 is a flowchart depicting still another method 1600 of computer-aided design using tracking to implement a computer-aided design function. At step 1602, a mathematical function representing a 3-dimensional geometry in a set of spatial coordinates is determined. For example, the 3-dimensional geometry may correspond to a zero isosurface of a scalar fields represented by the mathematical function. In this manner, a mathematical function may correspond to the surface of any 3-dimensional geometry such as a sphere, a cube, a cone, a torus, and/or the like. Combinations of functions (which may be combined into a single complex function) may correspond to more complex 3-dimensional geometry, such as the merger or superposition of two or more simpler 3-dimensional geometries.

At step 1604, the mathematical function of step 1602 is transformed into computer code that includes instructions for carrying out a multi-step computation of a value of the mathematical function at each particular point of interest in the spatial coordinates. The computer code may be, for example, bytecode that may be evaluated by a CPU, OpenGL shading language (GLSL) code that may be evaluated by a GPU, resulting in potential efficiency gains due to parallelism, or machine code with potential benefits such as faster CPU execution, more efficient memory access, and/or more efficient memory usage. For example, the multi-step computation may include hundreds, thousands, or millions of steps, each of which will be performed to determine the value of the mathematical function at a desired point in the space defined by the spatial coordinates.

At step 1606, the multi-step computation is repeatedly performed to compute a corresponding plurality of values of the mathematical function, each corresponding to a different point in the spatial coordinates. These points may, for example, lie within a bounding box of the spatial coordinates containing the 3-dimensional geometry, where the bounding box is either determined automatically by the dimensions of the 3-dimensional geometry, or specified by a user. Accordingly, the number of repetitions of the multi-step computation may be determined by the size of the 3-dimensional geometry in the coordinate space, the size of the user-specified or automatically determined bounding box containing the 3-dimensional geometry, and/or a desired spatial density of points chosen to represent the 3-dimensional geometry in various regions. In some cases, the density of points may vary across different portions of the 3-dimensional geometry. In other cases, the density of points may be the same throughout the 3-dimensional geometry.

At step 1608, each time the multi-step computation is performed to compute a value of the mathematical function, a computational characteristic is tracked across a plurality of steps of the multi-step computation. As discussed previously with respect to similar methods 1400 and 1500, tracking an identity operation can be used to identify steps within the multi-step calculation that do not contribute anything to the final value of the function at particular points, or that do not change the value of the function across subsets of steps. Among other benefits discussed below, this can allow improvements in calculation efficiency by “pruning” unnecessary calculation steps. Tracking partial derivatives across calculation steps can be used to orient surfaces correctly when a 3-dimensional shape is formed by the addition or subtraction of two or more other shapes, as described previously. Labeling and tracking selected values of the mathematical function corresponding to particular regions of the 3-dimensional geometry can also serve various useful purposes in a CAD design process.

At step 1610, a computer-aided design function relating to the 3-dimensional geometry is implemented based on the tracked computational characteristic. For instance, and as discussed above with regard to methods 1400 and 1500, identity operations tracked across multiple computation steps can be used to identify regions of the 3-dimensional geometry that have not been modified relative to a geometry that existed at some prior stage of a CAD workflow. In cases where multiple 3-dimensional geometries are combined into a more complex 3-dimensional geometry, tracking an identity operation may allow parts of the complex geometry to be represented by portions of the original geometries, while other parts of the complex geometry are represented by a more complex shape. In some cases, the various unmodified and modified portions of the complex 3-dimensional geometry may be color coded or otherwise distinguishable from each other.

A tracked computational characteristic also may be used to label regions of the 3-dimensional geometry based on a selected property of each region, such as whether or not the region has been modified from its original geometric representation, a desired density or fidelity of points in a region, a boundary condition to be applied to a region, or a tag that identifies a region in a manner that can be propagated to third-party software applications. Different surfaces within a 3-dimensional geometry may be separately tagged, in which case the presence of a pair of tags at certain points can be used to identify an edge where the corresponding surfaces meet, and the presence of other combinations of two or more tags can be used to identify particular points as corners or vertices of the 3-dimensional geometry.

When the tracked computational characteristic includes an identity operation, the implemented computer-aided design function may be associating a point on the 3-dimensional geometry with its creation in a computer-aided design workflow, allowing a user to easily determine when a particular point or region of the 3-dimensional geometry first appeared during a multi-step CAD design process. This may, for example, allow the user to select a point on a 3-dimensional geometry, and then conveniently or automatically navigate to a corresponding step of creation of that point in a CAD workflow. This may allow efficient revision of CAD design steps, without requiring significant time and effort to determine which design step to revise in order to edit a particular region of the 3-dimensional geometry.

### Exemplary Improvements to Computer-Aided Design Technology

This section more explicitly describes some exemplary improvements to computer-aided design technology provided by the present teachings. For example, and without limitation, the present teachings provide at least the following beneficial functions not provided by prior art CAD software programs and methods.

First, tracking computational characteristics such as identity operations across calculation steps allows for the preservation of user imported geometry, by providing information sufficient to determine which parts of the surface of a 3-dimensional CAD body, such as an implicit body, are fully influenced by a particular geometry, or by a CAD part that the user imported at the start of a CAD workflow. The user may have modified a part within their CAD workflow, but the part will remain unmodified in some areas, which are trackable and thus determinable according to the present teachings. Because tracking can determine where these unmodified regions are, when the user exports their work at the end of their CAD workflow, the final CAD body can preserve the original geometry wherever possible.

Next, tracking identity operations allows for a determination of which steps within the multi-step calculation do not contribute to the final value of a function representing a CAD body at particular points. This information can then be used to eliminate steps of the computation when calculating the value of the function for surrounding points, leading to potentially massive gains in computational efficiency. While computational “pruning” is generally known in the prior art, the present teachings provide an improved method of pruning based on tracking identity operations through a calculation.

Next, tracking identity operations across calculation steps can be used to associate a point on a 3-dimensional shape with its instant of creation in a computer-aided design workflow, allowing a user to determine conveniently when a particular point on the 3-dimensional shape first appeared during a CAD design process. This may, for example, allow the user to navigate to a corresponding step in a multi-step CAD workflow by selecting a point on the 3-dimensional shape, at which point the step of creating that point in the workflow will be identified based on analysis of the tracked identity operation(s). This may allow efficient troubleshooting or modification of specific points or regions of a 3-dimensional shape being modeled or designed.

Next, tracking partial derivatives across calculation steps can be used to orient surfaces correctly when a 3-dimensional shape is formed by the addition or subtraction of two or more other shapes.

Next, tracking labels or tags associated with regions of 3-dimensional shapes, based on a selected property of each region, can be used to identify regions having the selected property such as a boundary condition to be applied to a region, or a tag that identifies a region in a manner that can be propagated to third-party software applications. For example, if triangle meshes are exported, labels may be attached to the triangles representing that part of the surface. In a volume mesh export, labels may be attached to the cells representing the associated region of space. In a voxel grid export, labels may be added to the voxels.

Next, labels or tags propagated through calculations can be used to provide efficiency gains in specialized meshing. For example, if it is known that certain regions of a 3-dimensional CAD body require a particular structural density, such as a triangle mesh density, which is higher than the density in the remainder of the CAD body, the higher density regions may be tagged or labeled accordingly. This allows the higher density mesh to be produced only where it is needed, rather than everywhere throughout the CAD body, with corresponding savings to CPU usage and memory.

Next, tracking labels or tags applied to different surfaces of a 3-dimensional shape across calculation steps can be used to identify an edge where the surfaces meet, and/or the corners and vertices of the 3-dimensional shape.

Overall, the present teachings, particularly related to tracking computational characteristics across the steps of a multi-step computation of a scalar function that corresponds to a 3-dimensional CAD body, result in significant improvements in the field of computer-aided design.

### Further Support for Inventive Concepts of the Present Teachings

The following numbered paragraphs provide additional context and support for the inventive concepts of the present teachings.

A computer-implemented method, comprising:
determining, by a computing system, for a portion of a syntax representation of an implicit CAD body, a hash;
establishing, by the computing system, an implicit face of the implicit CAD body as those points on a surface of the implicit CAD body that track to the portion of the syntax
representation; and providing, by the computing system, using the implicit face, CAD functionality.

A1. The computer-implemented method of paragraph A, wherein the CAD functionality comprises one or more of simulation or extrusion.

A2. The computer-implemented method of paragraph A, wherein the syntax representation is an abstract semantic graph or an abstract syntax tree, and wherein the portion is a subgraph or subtree.

A3. The computer-implemented method of paragraph A, further comprising:
storing, by the computing system, along with the portion of the syntax representation, the hash.

A4. The computer-implemented method of paragraph A, wherein one or more of a secure hash algorithm or a message digest algorithm is used to determine the hash.

A5. The computer-implemented method of paragraph A, further comprising:
accessing, by the computing system, a stored hash for an implicit face; and
finding, by the computing system, in the syntax representation, a portion having a matching stored hash.

A6. The computer-implemented method of paragraph A, further comprising:
defining, by the computing system, one or more boundary conditions for the implicit face.

A7. The computer-implemented method of paragraph A, further comprising:
assigning, by the computing system using the hash, a color to the implicit face.

A8. The computer-implemented method of paragraph A, further comprising:
using, by the computing system, a tracker to perform one or more of:
making workflow decisions, or
pruning one or more of calculations or instructions.

A9. The computer-implemented method of paragraph A, wherein the syntax representation is interpreted using one or more of:
an implicit kernel that uses register-based bytecode, or
an implicit kernel that uses just-in-time compilation.

B. A system, comprising:
at least one processor; and
a memory storing instructions that, when executed by the at least one processor, cause the system to perform:
determining, for a portion of a syntax representation of an implicit CAD body, a hash;
establishing an implicit face of the implicit CAD body as those points on a surface of the implicit CAD body that track to the portion of the syntax representation; and
providing, using the implicit face, CAD functionality.

B1. The system of paragraph B, further comprising:
storing, along with the portion of the syntax representation, the hash.

B2. The system of paragraph B, further comprising:
accessing a stored hash for an implicit face; and
finding, in the syntax representation, a portion having a matching stored hash.

B3. The system of paragraph B, further comprising:
defining one or more boundary conditions for the implicit face.

B4. The system of paragraph B, wherein the syntax representation is interpreted using one or more of:
an implicit kernel that uses register-based bytecode, or
an implicit kernel that uses just-in-time compilation.

C. A non-transitory computer-readable storage medium including instructions that, when executed by at least one processor of a computing system, cause the computing system to perform a method, comprising:
determining, for a portion of a syntax representation of an implicit CAD body, a hash;
establishing an implicit face of the implicit CAD body as those points on a surface of the implicit CAD body that track to the portion of the syntax representation; and
providing, using the implicit face, CAD functionality.

C1. The non-transitory computer-readable storage medium of paragraph C, wherein the instructions, when further executed by the at least one processor of the computing system, further cause the computing system to perform:
storing, along with the portion of the syntax representation, the hash.

C2. The non-transitory computer-readable storage medium of paragraph C, wherein the instructions, when further executed by the at least one processor of the computing system, further cause the computing system to perform:
accessing a stored hash for an implicit face; and
finding, in the syntax representation, a portion having a matching stored hash.

C3. The non-transitory computer-readable storage medium of paragraph C, wherein the instructions, when further executed by the at least one processor of the computing system, further cause the computing system to perform:
defining one or more boundary conditions for the implicit face.

C4. The non-transitory computer-readable storage medium of paragraph C, wherein the syntax representation is interpreted using one or more of:
an implicit kernel that uses register-based bytecode, or
an implicit kernel that uses just-in-time compilation.

D. A method of computer-aided design, comprising:
determining a mathematical function corresponding to an implicit body;
representing the mathematical function by a syntax representation;
transpiling the syntax representation into computer code that includes instructions for carrying out a multi-step computation of a value of the function;
repeatedly performing the multi-step computation to compute a plurality of values of the function corresponding to different points on the implicit body;
each time the multi-step computation is performed, tracking at least one computational characteristic across a plurality of steps of the multi-step computation; and
using the tracked computational characteristic to implement a computer-aided design function relating to the implicit body.

D1. The method of paragraph D, wherein the at least one computational characteristic includes an identity operation.

D2. The method of paragraph D, wherein the at least one computational characteristic includes a partial derivative of the mathematical function.

D3. The method of paragraph D, wherein tracking the at least one computational characteristic includes recording the at least one computational characteristic in a margin datastructure having a one-to-one correspondence with registers containing outputs of the steps of the multi-step computation.

D4. The method of paragraph D, wherein tracking the at least one computational characteristic is performed with a visitor software pattern that tracks the at least one computational characteristic while remaining opaque to an interpreter executing the multi-step computation.

D5. The method of paragraph D, wherein the computer-aided design function includes distinguishing regions of the implicit body that have been modified from regions of the implicit body that have not been modified.

D6. The method of paragraph D, wherein the computer-aided design function includes labelling one or more regions of the implicit body based on a selected property of each region.

D7. The method of paragraph D, wherein the computer-aided design function includes associating a point on the implicit body with its step of creation in a multi-step computer-aided design workflow.

E. A method of computer-aided design, comprising:
determining a mathematical function representing a 3-dimensional shape;
transforming the function into computer code that includes instructions for carrying out a multi-step computation of a value of the function;
repeatedly performing the multi-step computation to compute a plurality of values of the function corresponding to a plurality of points within a bounding box of spatial coordinates containing the 3-dimensional shape;
each time the multi-step computation is performed, tracking a computational characteristic across a plurality of steps of the multi-step computation; and
implementing a computer-aided design function for the 3-dimensional shape based on the tracked computational characteristic.

E1. The method of paragraph E, wherein the tracked computational characteristic includes an identity operation selected from the group consisting of multiplying by one and adding zero.

E2. The method of paragraph E, wherein the tracked computational characteristic includes a partial derivative of the mathematical function, and the computer-aided design function is orienting a surface.

E3. The method of paragraph E, wherein tracking the computational characteristic includes recording the computational characteristic in a margin datastructure having a one-to-one correspondence with results of the steps of the multi-step computation.

E4. The method of paragraph E, wherein tracking the computational characteristic is performed with a visitor software pattern that is opaque to an interpreter executing the multi-step computation.

E5. The method of paragraph E, wherein the computer-aided design function includes distinguishing regions of the 3-dimensional shape that have been modified during a computer-aided design workflow from regions of the 3-dimensional shape that have not been modified during the computer-aided design workflow.

E6. The method of paragraph E, wherein the computer-aided design function includes labelling one or more regions of the 3-dimensional shape based on a selected property of each region.

E7. The method of paragraph E, wherein the computer-aided design function includes associating a point on the 3-dimensional shape with its creation in a computer-aided design workflow.

F. A method of computer-aided design, comprising:
determining a mathematical function representing a 3-dimensional geometry in a set of spatial coordinates;
transforming the mathematical function into computer code that includes instructions for carrying out a multi-step computation of a value of the function;
performing the multi-step computation a plurality of times to compute a corresponding plurality of values of the mathematical function, each value corresponding to a different point within a bounding box of the spatial coordinates containing the 3-dimensional geometry;
each time the multi-step computation is performed, tracking a computational characteristic across a plurality of steps of the multi-step computation; and
implementing a computer-aided design function relating to the 3-dimensional geometry based on the tracked computational characteristic.

F1 The method of paragraph F, wherein the tracked computational characteristic includes an identity operation or a partial derivative of the mathematical function.

F2. The method of paragraph F, wherein tracking the computational characteristic includes recording the computational characteristic in a margin datastructure or with a visitor software pattern.

F3. The method of paragraph F, wherein the computer-aided design function includes labelling one or more regions of the 3-dimensional geometry based on a selected property of each region or associating a point within the 3-dimensional geometry with its step of creation in a computer-aided design workflow.

1. A method of computer-aided design, comprising:
determining a mathematical function corresponding to an implicit body;
representing the mathematical function by a syntax representation;
transpiling the syntax representation into computer code that includes instructions for carrying out a multi-step computation of a value of the mathematical function;
repeatedly performing the multi-step computation to compute a plurality of values of the mathematical function corresponding to different points on the implicit body;
each time the multi-step computation is performed, tracking at least one computational characteristic across a plurality of steps of the multi-step computation; and
using the tracked at least one computational characteristic to implement a computer-aided design function relating to the implicit body.

2. The method of claim 1, wherein the at least one computational characteristic includes an identity operation.

3. The method of claim 1, wherein the at least one computational characteristic includes a partial derivative of the mathematical function.

4. The method of claim 1, wherein tracking the at least one computational characteristic includes recording the at least one computational characteristic in a margin datastructure having a one-to-one correspondence with registers containing outputs of the steps of the multi-step computation.

5. The method of claim 1, wherein tracking the at least one computational characteristic is performed with a visitor software pattern that tracks the at least one computational characteristic while remaining opaque to an interpreter executing the multi-step computation.

6. The method of claim 1, wherein the computer-aided design function includes distinguishing regions of the implicit body that have been modified from regions of the implicit body that have not been modified.

7. The method of claim 1, wherein the computer-aided design function includes labelling one or more regions of the implicit body based on a selected property of each region.

8. The method of claim 1, wherein the computer-aided design function includes associating a point on the implicit body with its step of creation in a multi-step computer-aided design workflow.

9. A method of computer-aided design, comprising:
determining a mathematical function representing a 3-dimensional shape;
transforming the mathematical function into computer code that includes instructions for carrying out a multi-step computation of a value of the mathematical function;
repeatedly performing the multi-step computation to compute a plurality of values of the mathematical function corresponding to a plurality of points within a bounding box of spatial coordinates containing the 3-dimensional shape;
each time the multi-step computation is performed, tracking a computational characteristic across a plurality of steps of the multi-step computation; and
implementing a computer-aided design function for the 3-dimensional shape based on the tracked computational characteristic.

10. The method of claim 9, wherein the tracked computational characteristic includes an identity operation selected from the group consisting of multiplying by one and adding zero.

11. The method of claim 9, wherein the tracked computational characteristic includes a partial derivative of the mathematical function, and the computer-aided design function is orienting a surface.

12. The method of claim 9, wherein tracking the computational characteristic includes recording the computational characteristic in a margin datastructure having a one-to-one correspondence with results of the steps of the multi-step computation.

13. The method of claim 9, wherein tracking the computational characteristic is performed with a visitor software pattern that is opaque to an interpreter executing the multi-step computation.

14. The method of claim 9, wherein the computer-aided design function includes distinguishing regions of the 3-dimensional shape that have been modified during a computer-aided design workflow from regions of the 3-dimensional shape that have not been modified during the computer-aided design workflow.

15. The method of claim 9, wherein the computer-aided design function includes labelling one or more regions of the 3-dimensional shape based on a selected property of each region.

16. The method of claim 9, wherein the computer-aided design function includes associating a point on the 3-dimensional shape with its creation in a computer-aided design workflow.

17. A method of computer-aided design, comprising:
determining a mathematical function representing a 3-dimensional geometry in a set of spatial coordinates;
transforming the mathematical function into computer code that includes instructions for carrying out a multi-step computation of a value of the mathematical function;
performing the multi-step computation a plurality of times to compute a corresponding plurality of values of the mathematical function, each value corresponding to a different point within a bounding box of the spatial coordinates containing the 3-dimensional geometry;
each time the multi-step computation is performed, tracking a computational characteristic across a plurality of steps of the multi-step computation; and
implementing a computer-aided design function relating to the 3-dimensional geometry based on the tracked computational characteristic.

18. The method of claim 17, wherein the tracked computational characteristic includes an identity operation or a partial derivative of the mathematical function.

19. The method of claim 17, wherein tracking the computational characteristic includes recording the computational characteristic in a margin datastructure or with a visitor software pattern.

20. The method of claim 17, wherein the computer-aided design function includes labelling one or more regions of the 3-dimensional geometry based on a selected property of each region or associating a point within the 3-dimensional geometry with its step of creation in a computer-aided design workflow.
